(19) United States
(12) Patent Application Publication
(10) Pub. No.: US 2008/0029763 A1
(43) Pub. Date: Feb. 7, 2008

(54) Transmission Circuit, Connecting Sheet, Probe Sheet, Probe Card, Semiconductor Inspection System and Method of Manufacturing Semiconductor Device

(76) Inventors: Susumu Kasukabe, Yokohama (JP); Terutaka Mori, Urayasu (JP); Yasunori Narizuka, Hiratsuka (JP); Norio Chujo, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/740,301

(22) Filed: Apr. 26, 2007

(30) Foreign Application Priority Data
May 16, 2006 (JP) 2006-136596

(51) Int. Cl. H01L 23/48; G01R 31/26; H01L 23/58; H01L 29/40

(52) U.S. Cl. 257/48; 257/664; 257/784; 438/17; 257/E29.111; 257/E23.01; 257/E21.521

(57) ABSTRACT

A probe sheet or a connecting sheet with good transmission characteristics and flexibility comprising contact terminals capable of contacting at a plurality of points and in high density, without applying damages on an electrode pad which is a contact subject is provided. Further, a high-speed transmission circuit capable of designing signal wirings with aligned impedance to have wide width even with a thin insulating film is achieved to provide a probe sheet or a connecting sheet with reduced loss of high-speed transmission signals. Moreover, the transmission circuit is applied to a probe card using a probe sheet, an inspecting method of (a method of manufacturing) a semiconductor device using the same, and a connecting sheet having an excellent high-frequency characteristic.

### CROSS-REFERENCE TO RELATED APPLICATION

The present application claims priority from Japanese Patent Application No. JP 2006-136596 filed on May 16, 2006, the content of which is hereby incorporated by reference into this application.

### TECHNICAL FIELD OF THE INVENTION

The present invention relates to a technique effectively applied to a transmission circuit, a connecting sheet, a probe sheet, a probe card, a semiconductor inspection system, and a method of manufacturing a semiconductor device.

### BACKGROUND OF THE INVENTION

For example, as in a manufacturing technique of the semiconductor device, FIG. 18 mainly shows one example of a flow of respective inspection steps in a manufacturing process of semiconductor devices implemented after forming semiconductor element circuits on a wafer, by exemplifying a package product, a bare chip and a CSP as typical shipping forms of semiconductor devices.

In the manufacturing process of the semiconductor device, three main inspections are implemented as shown in FIG. 18. There exist: first a wafer inspection which is implemented to a wafer form in which semiconductor element circuits and electrodes are formed on the wafer, and comprehends a conduction state and an operative condition of electric signal of the semiconductor elements; second a burn-in inspection to take out semiconductor elements which are unstable in a high temperature state, a high applied voltage or the like; and finally a sorting inspection comprehending the product performance of semiconductor devices before shipping them.

The wafer is provided with a plurality of semiconductor devices (chips) on a surface thereof, and is individually separated so as to be supplied for using. A plurality of electrodes are provided in rows on the surface of the individually separated semiconductor device. In order to industrially product a large number of that semiconductor devices, and inspect electric characteristics thereof, there is used a connection device (hereinafter, referred to as a conventional art 1) constructed by a probe formed of a tungsten needle protruding diagonally from a probe card. In the inspection by the connection device, there is employed a method of scratching the electrode on the basis of a contact pressure utilizing the flexure of the probe so as to secure the contact and inspect electric characteristics.

In recent years, according to the semiconductor elements getting formed in high density, there is promoted narrower pitch and high pin count of the inspecting probe in the inspecting step in manufacturing of the semiconductor elements, and it is desired to develop an inspection system for semiconductor elements, which uses a connection device which can implement the probing to the semiconductor elements of narrow pitch and high pin count in a step where a high-speed electric signal is transmitted between the electrode of the semiconductor element and the inspection circuit to inspect the element in actual operation, and is further capable of preventing a damage applied to the semiconductor elements. Accordingly, as a transmission circuit for transmitting the high-speed signal, there is generally used a method using a probe sheet formed by a photolithography technique where a ground layer is formed on a surface facing signal wirings formed on an insulating layer, followed by forming microstrip lines.

As an inspection method and an inspection system which can implement an inspection of characteristics of the semiconductor element in the case where the high density and the narrow pitch of the semiconductor element are further promoted and an operation test by the high-speed signal is necessary, there is a technique described in Non-patent Document 1 (Proceedings of IEEE International Test Conference (ITC) 1988, pp. 601-607). FIG. 15 is a schematic view of a structure thereof, and FIG. 16 is an enlarged perspective view of a main part thereof. The probe for inspecting a conductor used here has a structure obtained by: forming wirings 41 on an upper surface of a flexible dielectric membrane 40 by a photolithography technique; forming a ground layer 44 on a lower surface of the dielectric membrane 40; and forming a semispherical bump 43 by plating in a through hole 42 of the dielectric membrane 40 provided at a position corresponding to the electrode of the semiconductor to be inspected. The bump 43 is utilized as a contact terminal. This technique is a method where the bump 43 is connected to an inspection circuit (not shown) via the wiring 41 formed on the front surface of the dielectric membrane 40 and a wiring substrate 45, and caused to scratch the electrode of the semiconductor element to be inspected by a leaf spring 46 to give and receive a signal to inspect.

Further, there is a technique described in Non-patent Document 2 (a brochure of Cascade Microtech Inc. (PYRAMIDS-0497-J0997-0502)). FIG. 17 is a schematic view of a wiring structure thereof. This is a method of forming a ground wiring 48 having a wide wiring width in an area just below a wiring 47 and a grid-like patterned ground layer 48a lapping over the ground wiring, on a surface facing an insulating layer (not shown) on which the wiring 47 is formed.

### SUMMARY OF THE INVENTION

In the meanwhile, in the manufacturing technique of the semiconductor device, it is desired to develop an inspection system of semiconductor elements using a connection device which can transmit high-speed electric signals between an electrode of narrow-pitch and high pin count semiconductor elements and an inspection circuit so as to inspect in actual operation, or a connecting sheet (an interposer) which can transmit high-speed electric signals. Accordingly, the above technique is studied from this standpoint.

The conventional probes formed by tungsten needles and the probes mentioned above formed by the semispherical bumps secure the contact with electrodes which are made of a contacted material such as an aluminum electrode and a solder electrode an oxide is formed on the material surface thereof in a manner where the contact terminal is scratched on the electrode to remove the oxide so as to have a contact with the metal conductor material underneath. As a result, shavings of the electrode material are generated by scratching the electrode by the contact terminal, thereby causing a short circuit between the wirings and generating foreign materials. Further, since the contact is secured by the probe scratched on the electrode while applying a load of several hundreds mN or more, damages are frequently applied to the electrode.

As described above, in the method of taking the bump formed by plating in a part of copper wirings shown in FIGS. 15, 16, and 17 as the probe, since a leading end portion of the bump is formed in a flat shape or a semispherical shape, its contact resistance becomes unstable with respect to the contacted material an oxide is formed on the material surface such as an aluminum electrode or a solder electrode, and it is necessary to make the load at contacting equal to or more than several hundreds mN. However, a problem is arisen if the load at contacting is made too large. In other words, since high integration of the semiconductor element is promoted, and the high-density, high pin count and narrow-pitch electrodes are formed on the front surface of the semiconductor element, a large number of active elements or fine wirings are often formed just below the electrode. If the contact pressure of the probe on the electrode while inspecting the semiconductor element is too strong, there is a risk that damages are applied to the electrodes, and the active elements and wirings just below the electrodes. Accordingly, it is necessary to control the operation carefully when probing, thus lowering of throughput may be posed.

Further, since it is expected that variations are occurred in the shape or the like of the bump, a great contact pressure is necessary as a whole for completely contacting tips having poor contacts, and there is a problem that an excessive contact pressure is partly applied. Accordingly, in order to securely bring the probe sheet into contact with the electrode to be contacted at a time of pressing, in addition to the shape of the contact terminal which passes through the oxide or the like on the front surface of the material to be contacted and can secure stable contact characteristics, a probe sheet having the flexibility is needed.

In the microstrip type sheet in which the ground layer is formed on the lower surface of the insulating layer as shown in FIGS. 15 and 16, for example, in the case that a thickness of the insulating layer is 12.5 μm, a wiring width to control the impedance to be 50Ω comes to about 25 μm, therefore, a surface area of the signal wiring is reduced. A loss is enlarged depending on the shape as the surface area of the wiring being smaller under the influence of the skin effect of the high-speed transmission signal, and the metal ground layer is formed on a whole underneath of the insulating layer, therefore the flexibility of the probe sheet is deteriorated, and it is hard to secure a stable contact.

The sheet in which the ground layer is formed in a grid shape on one surface of the insulating layer shown in FIG. 17 can secure the flexibility of the probe sheet to some extent, however, there is a problem that the wiring width to control the impedance becomes narrow in the same manner as the example mentioned above, whereby the loss is enlarged.

The present invention provides a probe sheet or a connecting sheet having contact terminals which can be brought into contact with an electrode pad to be contacted at a plurality of points and with a high density without applying any damages to the electrode pad, and having good transmission characteristics and the flexibility.

Further, the present invention provides a probe sheet or a connecting sheet in which a loss of a high-speed transmission signals is reduced by achieving a high-speed transmitting circuit in which a width of an impedance-controlled signal wiring wide, even with an insulating film having a small thickness.

The above and other objects and novel characteristics of the present invention will be apparent from the description of this specification and the accompanying drawings.

The typical ones of the inventions disclosed in this application will be briefly described as follows.

(1) A transmission circuit having a signal wiring formed on an upper surface of an insulating layer, and a ground wiring formed on a lower surface of the insulating layer, wherein the transmission circuit is designed by a wiring structure where the ground wiring just below the signal wiring while sandwiching the insulating layer is partly removed.

(2) A transmission circuit having a signal wiring formed on an upper surface of an insulating layer, and a ground wiring formed on a lower surface of the insulating layer, wherein the transmission circuit is designed by a wiring structure where the ground wiring just below the signal wiring while sandwiching the insulating layer is partly removed, and the signal wiring and the ground wiring are formed in a radial pattern.

(3) The transmission circuit according to the item (2), wherein one or a plurality of wirings conducting the ground wirings mutually are provided in the middle of the ground wirings of the radial pattern.

(4) The transmission circuit according to any one of the items (1) to (3), wherein the ground wiring is formed by two ground wirings which are spaced at a width equal to or more than a width of the signal wiring, and have a width smaller than the twofold width of the signal wiring.

(5) The transmission circuit according to any one of the items (1) to (3), wherein the signal wiring is formed by a differential line pair, one ground wiring is provided just below a position between the lines of the differential line pair, and the ground wirings are provided on surfaces below outer sides of the differential line pair respectively.

(6) The transmission circuit according to the item (5), wherein an interval of the differential line pair is equal to or more than the width of the differential wiring, and the ground wiring is formed by a ground wiring having a width smaller than the twofold width of the differential wiring.

(7) A probe sheet comprising: contact terminals for wafer electrodes disposed corresponding to an arrangement of electrodes of semiconductor elements formed on a wafer; wirings drawn from the contact terminals for connecting wafer electrodes; and contact terminals for a substrate electrically connected to the wiring, wherein the wirings configure the transmission circuit according to any one of the items (1) to (6).

(8) The probe sheet according to the item (7), wherein the contact terminals for wafer electrodes are formed by using anisotropic etching pits of a single crystal substrate as the cast of the contact terminals.

(9) The probe sheet according to the item (7), wherein both of the contact terminals for wafer electrodes and the contact terminals for the substrate are formed by using anisotropic etching pits of the single crystal substrate as the cast of contact terminals.

(10) A probe card comprising: contact terminals for wafer electrodes brought into contact with electrodes provided on a wafer; wirings drawn from the contact terminals for wafer electrodes; contact terminals for a substrate electrically connected to the wirings; and a multilayer wiring substrate having electrodes electrically connected to the contact terminals for the substrate, wherein the wirings configure the transmission circuit according to any one of the items (1) to (6).

(11) The probe card according to the item (10), wherein the contact terminals for wafer electrodes are configured by pyramidal shape or truncated pyramidal shape terminals formed by using anisotropic etching pits of a single crystal substrate as the cast of contact terminals.

(12) A semiconductor inspection system comprising: a wafer stage to mount a wafer thereon; contact terminals for wafer electrodes brought into contact with electrodes of semiconductor elements formed on the wafer; and a probe card electrically connected to a tester to test electric characteristics of the semiconductor elements, wherein the probe card has contact terminals for wafer electrodes brought into contact with electrodes provided on the wafer, wirings drawn from the contact terminals for wafer electrodes, contact terminals for a substrate electrically connected to the wirings, and a multilayer wiring substrate provided with electrodes electrically connected to the contact terminals for the substrate, wherein the wirings configure the transmission circuit according to any one of the items (1) to (6).

(13) The semiconductor inspection system according to the item (12), wherein both or one of the contact terminals for wafer electrodes and the contact terminals for the substrate are in pyramidal shape or truncated pyramidal shape formed by using anisotropic etching pits of a single crystal substrate as the cast of contact terminals.

(14) A method of manufacturing a semiconductor device including the steps of: forming circuits on a wafer so as to form semiconductor elements; inspecting electric characteristics of the semiconductor elements; and dicing the wafer so as to divide per the semiconductor element, wherein the step of inspecting electric characteristics of the semiconductor elements inspects the semiconductor elements by using: a probe sheet comprising contact terminals for wafer electrodes brought into contact with electrodes of the semiconductor elements, wirings drawn from the contact terminals for wafer electrodes, and contact terminals for a substrate electrically connected to the wirings; and a probe card comprising a multilayer wiring substrate having electrodes electrically connected to the contact terminals for the substrate, and the wirings configure the transmission circuit according to any one of the items (1) to (6).

(15) A method of manufacturing a semiconductor device including the steps of: forming circuits on a wafer so as to form semiconductor elements; molding the wafer by a resin; and inspecting electric characteristics of the semiconductor elements formed on the molded wafer, wherein the step of inspecting electric characteristics of the semiconductor elements inspects the semiconductor element by using: a probe sheet comprising contact terminals for wafer electrodes brought into contact with electrodes of the semiconductor elements, wirings drawn from the contact terminals for wafer electrodes, and contact terminals for a substrate electrically connected to the wirings; and a probe card comprising a multilayer wiring substrate having electrodes electrically connected to the contact terminals for the substrate, and the wirings configure the transmission circuit according to any one of the items (1) to (6).

(16) The method of manufacturing a semiconductor device according the item (14) or (15), wherein both or one of the contact terminals for wafer electrodes and the contact terminals for the substrate are in pyramidal shape or truncated pyramidal shape formed by using anisotropic etching pits of a single crystal substrate as the cast of contact terminals.

(17) A connecting sheet comprising: a first contact terminal for an electrode to be contacted with an electrode provided on a first contact subject; a second contact terminal for an electrode to be contacted with an electrode provided on a second contact subject; and wirings drawn to the second contact terminal for an electrode from the first contact terminal for an electrode, wherein the wirings configure the transmission circuit according to the items (1) to (6).

(18) The connecting sheet according to the item (17), wherein both or one of the first contact terminal for an electrode and the second contact terminal for an electrode are formed by using anisotropic etching pits of a single crystal substrate as the cast of contact terminals.

These and other objects, features and advantages of the invention will be apparent from the following more particular description of preferred embodiments of the invention, as illustrated in the accompanying drawings.

### BRIEF DESCRIPTIONS OF THE DRAWINGS

FIG. 1A is a perspective view showing a wafer corresponding to a contacted subject in which semiconductor elements (chips) are arranged according to an embodiment of the present invention;

FIG. 1B is a perspective view showing the semiconductor element (chip);

FIG. 2A-1 is a diagram of a basic configuration of transmission circuit pattern of a single signal wiring type according to the present invention, in an embodiment of the present invention;

FIG. 2A-2 is a schematic view of electric lines of force for FIG. 2A-1;

FIG. 2B-1 is a diagram of a basic configuration in which a ground wiring is formed just below a signal wiring;

FIG. 2B-2 is a schematic view of electric lines of force for FIG. 2B-1;

FIG. 2C-1 is a diagram of a basic configuration of a microstrip;

FIG. 2C-2 is a schematic view of electric lines of force for FIG. 2C-1;

FIG. 3A-1 is a view of a basic configuration of a transmission circuit pattern of a differential signal wiring type according to the present invention, in an embodiment of the present invention;

FIG. 3A-2 is a schematic view of electric lines of force for FIG. 3A-1;

FIG. 3B-1 is a diagram of a basic configuration of a differential signal wiring of a microstrip;

FIG. 3B-2 is a schematic view of electric lines of force for FIG. 3B-1;

FIG. 4A is a plan schematic view showing an example of a probe sheet according to the present invention, in an embodiment of the present invention;

FIG. 4B is a perspective view of a main part showing an example of a probe sheet configuration of the single wiring type of FIG. 2A-1, a contact terminal is formed thereon;

FIG. 4C is a perspective view of a main part showing an example of a probe sheet configuration of the differential wiring type of FIG. 3A-1, a contact terminals are formed thereon;

FIG. 5A is a diagram showing an example of measurement results of bandpass characteristic of the single signal wiring type transmission circuit pattern according to the present invention and a conventional microstrip type, in an embodiment of the present invention;

FIG. 5B is a diagram showing an example of a measurement result of a transmission waveform of a probe sheet using the single signal wiring type transmission circuit pattern according to the present invention;

FIG. 5C is a diagram showing an example of a measurement result of a transmission waveform of a probe sheet using the differential signal wiring type transmission pattern according to the present invention;

FIG. 6A is a diagram showing a part of a manufacturing process to form a probe sheet (structure) part in a probe card according to the present invention, in a first embodiment of the present invention;

FIG. 6B is a diagram showing a part of the manufacturing process to form the probe sheet (structure) part in the probe card according to the present invention, in the first embodiment of the present invention;

FIG. 6C is a diagram showing a part of the manufacturing process to form the probe sheet (structure) part in the probe card according to the present invention, in the first embodiment of the present invention;

FIG. 6D is a diagram showing a part of the manufacturing process to form the probe sheet (structure) part in the probe card according to the present invention, in the first embodiment of the present invention;

FIG. 6E is a diagram showing a part of the manufacturing process to form the probe sheet (structure) part in the probe card according to the present invention, in the first embodiment of the present invention;

FIG. 6F is a diagram showing a part of the manufacturing process to form the probe sheet (structure) part in the probe card according to the present invention, in the first embodiment of the present invention;

FIG. 6G is a diagram showing a part of the manufacturing process to form the probe sheet (structure) part in the probe card according to the present invention, in the first embodiment of the present invention;

FIG. 7A is a diagram showing a manufacturing processes subsequent to FIGS. 6A to 6G, in the first embodiment of the present invention;

FIG. 7B is a diagram showing a manufacturing processes subsequent to FIGS. 6A to 6G, in the first embodiment of the present invention;

FIG. 7C is a diagram showing a manufacturing processes subsequent to FIGS. 6A to 6G, in the first embodiment of the present invention;

FIG. 8A is a diagram showing an other manufacturing processes to form a probe sheet (structure) part in a probe card according to the present invention, in a second embodiment of the present invention;

FIG. 8B is a diagram showing an other manufacturing processes to form the probe sheet (structure) part in the probe card according to the present invention, in the second embodiment of the present invention;

FIG. 8C is a diagram showing an other manufacturing processes to form the probe sheet (structure) part in the probe card according to the present invention, in the second embodiment of the present invention;

FIG. 8D is a diagram showing an other manufacturing processes to form the probe sheet (structure) part in the probe card according to the present invention, in the second embodiment of the present invention;

FIG. 8E is a diagram showing an other manufacturing processes to form the probe sheet (structure) part in the probe card according to the present invention, in the second embodiment of the present invention;

FIG. 9 is a perspective view showing disintegrated main parts of FIG. 7C and FIG. 8E, in an embodiment of the present invention;

FIG. 10A is a diagram showing an other example of a manufacturing process to form a probe sheet (structure) part in a probe card according to the present invention, in a third embodiment of the present invention;

FIG. 10B is a diagram showing an other example of a manufacturing process to form the probe sheet (structure) part in the probe card according to the present invention, in the third embodiment of the present invention;

FIG. 10C is a diagram showing an other example of a manufacturing process to form the probe sheet (structure) part in the probe card according to the present invention, in the third embodiment of the present invention;

FIG. 10D is a diagram showing another example of a manufacturing process to form the probe sheet (structure) part in the probe card according to the present invention, in the third embodiment of the present invention;

FIG. 10E is a diagram showing an other example of a manufacturing process to form the probe sheet (structure) part in the probe card according to the present invention, in the third embodiment of the present invention;

FIG. 10F is a diagram showing an other example of a manufacturing process to form the probe sheet (structure) part in the probe card according to the present invention, in the third embodiment of the present invention;

FIG. 11A is a diagram showing an other example of a manufacturing process to form a probe sheet (structure) part in a probe card according to the present invention, in a fourth embodiment of the present invention;

FIG. 11B is a diagram showing an other example of a manufacturing process to form the probe sheet (structure) part in the probe card according to the present invention, in the fourth embodiment of the present invention;

FIG. 11C is a diagram showing an other example of a manufacturing process to form the probe sheet (structure) part in the probe card according to the present invention, in the fourth embodiment of the present invention;

FIG. 11D is a diagram showing another example of a manufacturing process to form the probe sheet (structure) part in the probe card according to the present invention, in the fourth embodiment of the present invention;

FIG. 12 is a perspective view showing disintegrated main parts of FIG. 10F and FIG. 1D, in an embodiment of the present invention;

FIG. 13 is a diagram showing a whole schematic structure of an example of an inspection system according to the present invention, in an embodiment of the present invention;

FIG. 14A is a diagram showing an example of a schematic cross sectional view of a configuration of a connecting sheet according to the present invention, in a fifth embodiment of the present invention;

FIG. 14B is a diagram showing an example of a schematic cross sectional view of a configuration of a connecting sheet according to the present invention, in the fifth embodiment of the present invention;

FIG. 14C is a diagram showing an example of a schematic cross sectional view of a configuration of a connecting sheet according to the present invention, in the fifth embodiment of the present invention;

FIG. 14D is a diagram showing an example of a schematic cross sectional view of a configuration of a connecting sheet according to the present invention, in the fifth embodiment of the present invention;

FIG. 15 is a cross sectional view of a main part of a semiconductor element inspection system using a conventional bump formed by plating;

FIG. 16 is a perspective view showing the bump portion formed by plating in FIG. 15;

FIG. 17 is a perspective view schematically showing a wiring configuration of a main part of a semiconductor element inspection system using the conventional bump formed by plating; and

FIG. 18 is a process chart showing an example of commonly used inspection steps of semiconductor devices.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

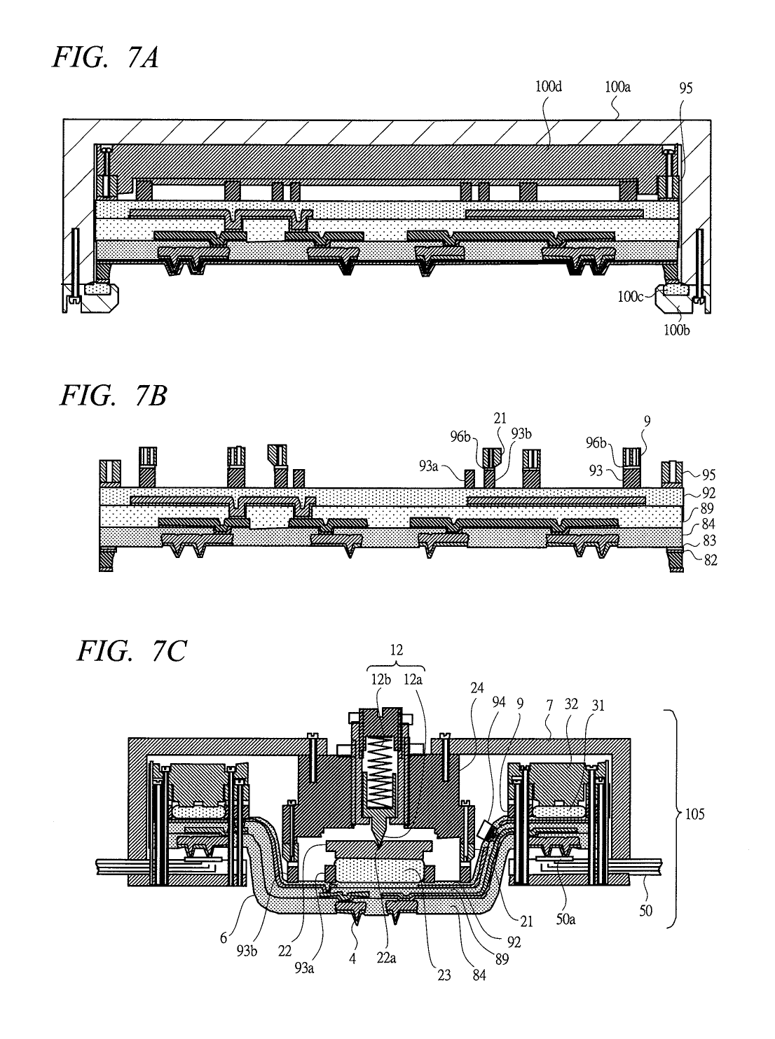

In the present specification, main terms are defined as follows. A semiconductor device may be, regardless of its form, a wafer on which circuits are formed, a semiconductor element, and a packaged semiconductor element (QFP, BGA, CSP and the like). A probe sheet means a thin film structured such that contact terminals to be contacted with an inspected subject and wirings drawn therefrom are provided, and the wirings have electrodes formed for external connection, and its thickness is aimed at being about between 10 μm and 100 μm. A probe card indicates a structure (for example, a structure shown in FIG. 7C) having a terminal contacted with the inspected subject, a multilayer wiring substrate, and the like. A semiconductor inspection system indicates an inspection system having a supporting system for samples to mount the probe card and the inspected subject thereon.

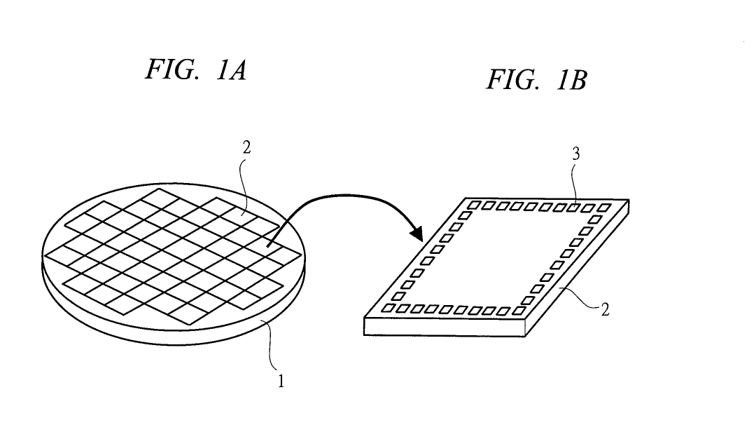

A plurality of semiconductor elements (chips) 2 for LSI corresponding to an example of an inspected subject are formed on a wafer 1 as shown in FIG. 1, and are thereafter divided so as to be supplied for use. FIG. 1A is a perspective view showing the wafer 1 in which a plurality of semiconductor elements 2 for LSI are provided side by side, and FIG. 1B is a perspective view showing one semiconductor element 2 in an enlarged manner. A plurality of electrodes 3 are arranged on a front surface of the semiconductor element 2 along its periphery.

Meanwhile, the semiconductor element is under a condition that higher density and narrower pitch of the electrode 3 are further promoted as getting higher integration. As the narrow pitch of the electrode, the pitch becomes equal to or less than about 0.1 mm, for example, it comes to 0.08 mm, 0.04 mm or less. As the high density of the electrode, the electrode arranged in one row tends to be arranged in two rows along the periphery, and further arranged on the whole surface.

Further, there is a tendency that there is implemented a high-temperature operation test (85 to 150° C.) more definitely comprehending characteristics and reliability of the semiconductor element by testing the semiconductor element in operation at a high temperature.

A semiconductor inspection system according to the present invention can correspond to the high density and the narrow pitch of the electrode, and can implement an inspection by simultaneous probing of multiple chips and an inspection with high-speed electric signals (100 MHz to 20 GHz).

Further, a displacement of a leading end portion of the probe due to an atmospheric temperature is prevented by using a material having a thermal resistance of 150° C. and a linear expansion coefficient which is the same level as that of the inspected subject, as a construction material of a part of the probe card in the semiconductor inspection system.

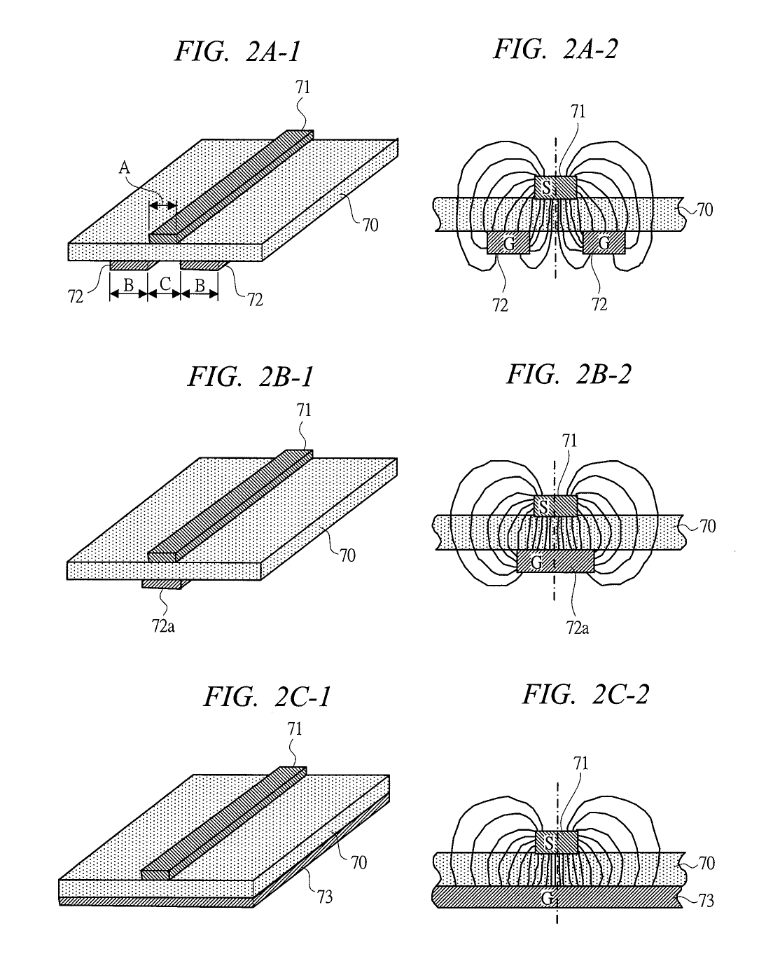

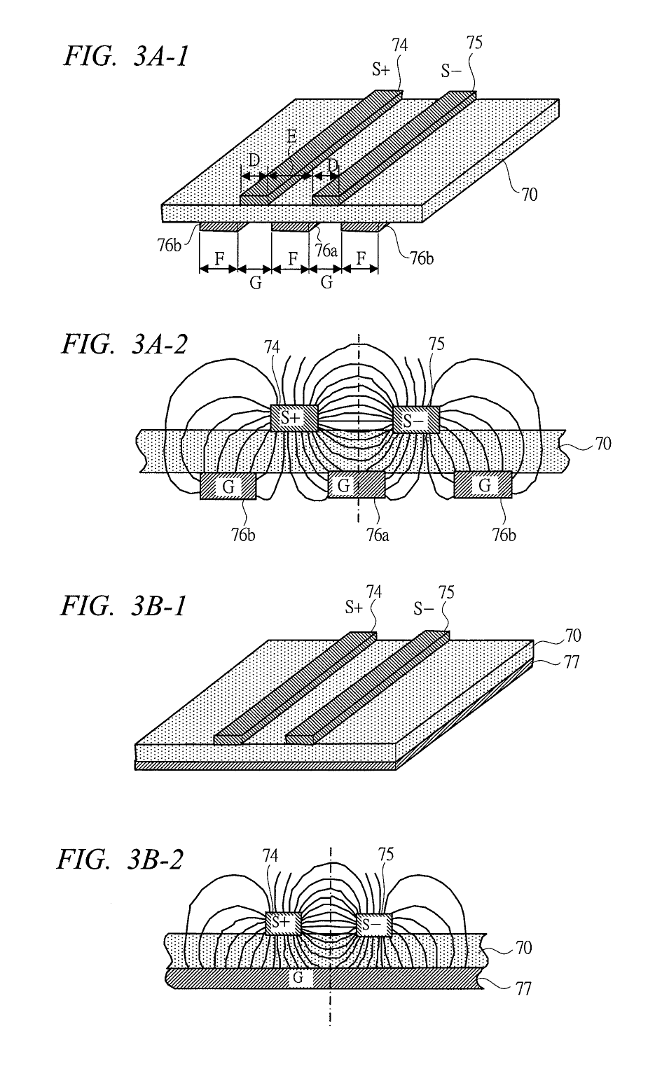

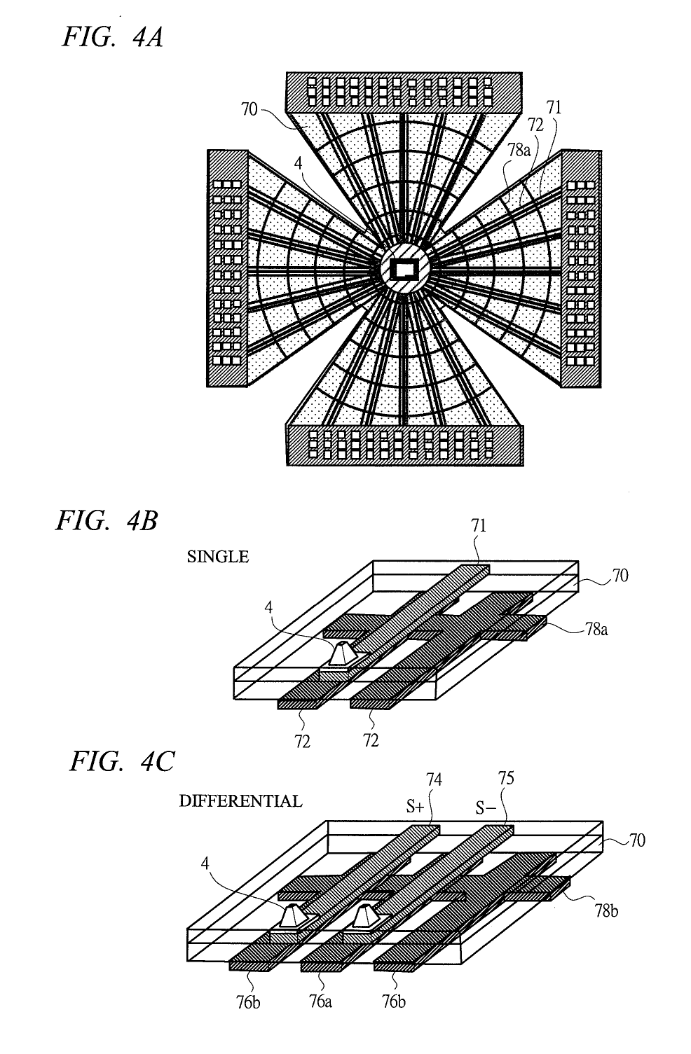

A description will be given of a pattern of a high-speed transmitting circuit according to the present invention with reference to FIG. 2, FIG. 3, and FIG. 4.

FIG. 2 shows a perspective view of a main part of a representative example of a ground wiring and a ground layer in a single signal wiring system. FIG. 2A-1 is a diagram of a basic configuration of a transmission circuit pattern of the single signal wiring type according to the present invention, and FIG. 2A-2 is a schematic view of electric lines of force of FIG. 2A-1. To compare with the configuration of the transmission circuit pattern according to the present invention, FIG. 2B-1 is a diagram of a basic configuration in which a ground wiring 72a is formed just below a signal wiring 71, FIG. 2B-2 is a schematic view of electric lines of force for FIG. 2B-1, FIG. 2C-1 is a diagram of a basic configuration of a conventional microstrip in which a ground layer 73 is formed on a surface facing to an insulating layer 70 on which the signal wiring 71 is formed, and FIG. 2C-2 is a schematic view of electric lines of force for FIG. 2C-1.

The transmission circuit shown in FIG. 2A-1 is set to have a wiring structure in which the signal wiring 71 is formed on the insulating layer 70, and two ground wirings 72 having a width B smaller than twice of a width A of the signal wiring 71 are formed on the facing surface just below the insulating layer 70 on the facing surface of the signal wiring 71 so as to be spaced at an interval C which is larger than the width A of the signal wiring 71.

In other words, the transmission circuit shown in FIG. 2A-1 is set to have the wiring structure in which the signal wiring 71 is formed on an upper surface of the insulating layer 70, the ground wiring 72 is formed on a lower surface of the insulating layer 70, and the ground wiring 72 just below the signal wiring 71 sandwiching the insulating layer 70 is partly removed, and particularly, the ground wiring 72 is configured by two ground wirings which are spaced at the interval equal to or more than the width A of the signal wiring 71, and are smaller than twice of the width A of the signal wiring 71 (C>A, B<2×A).

FIG. 3 shows a perspective view of a main part of a representative example of a ground wiring and a ground layer according to a differential signal wiring system. FIG. 3A-1 is a diagram of a basic configuration of the differential signal wiring type transmission circuit pattern according to the present invention, and FIG. 3A-2 is a schematic view of electric lines of force for FIG. 3A-1. To compare with the structure of the transmission circuit pattern according to the present invention, FIG. 3B-1 shows a diagram of a basic configuration of a differential signal wiring of the conventional microstrip having a ground layer 77 formed thereon, and FIG. 3B-2 shows a schematic diagram of electric lines of force for FIG. 3B-1.

The transmission circuit shown in FIG. 3A-1 is set to have a wiring structure in which one ground wiring 76a is formed just below a portion between lines 74 and 75 of a differential line pair formed on the insulating layer 70, and a ground wiring 76b is formed on a lower surface of the insulating layer 70 at an outer side of each of the differential wirings 74 and 75. For example, the structure may be made such that a wiring interval E of the differential line pair 74 and 75 is set to be equal to or more than a width D of the differential wiring, and the ground wirings 76a and 76b are formed to have a width F smaller than twice of the width D of the differential wiring (E>D, F<2×D). Also in this structure, it is desirable to arrange the ground wirings 76a and 76b so as to be spaced at a interval G equal to or more than the width D of the signal wiring 74 (75) (G>D).

A description will be given of a configuration of a probe sheet according to the present invention with reference to FIG. 4.

FIG. 4A is a plan schematic view showing an example of an embodiment of the probe sheet according to the present invention. Each of the ground wirings 72 of the single wiring type is configured so as to be conducted by a concentrically arranged ground wires 78a.

In this case, FIG. 4A is a diagram showing the single wiring type probe sheet shown in FIG. 2, however, it goes without saying that the structure may be made such that the probe sheet may be constituted by the differential wiring type probe sheet or a probe sheet in which both types are mixed, each of the ground wirings is conducted by the concentrically arranged ground wire 78a or the ground wiring group (72), or the ground wiring group (76a, 76b) is conducted by the ground wiring 78b or 78a.

FIG. 4B is a perspective view of a main part of the configuration of the single wiring type probe sheet in FIG. 2A-1. The probe sheet configuration is made such that the signal wiring 71 on which a contact terminal 4, the ground wiring 72, and the ground wiring 78a conducting the ground wiring group (72) are formed on the insulating layer 70.

FIG. 4C is a perspective view of a main part of the configuration of the differential wiring type probe sheet in FIG. 3A-1. The configuration of the probe sheet is made such that the signal wirings 74 and 75 on which the contact terminal 4 is formed, the ground wirings 76a and 76b, and the ground wire 78b conducting the ground wiring group (76a, 76b) are formed on the insulating layer 70.

In this case, whichever the probe sheet is of the single wiring type or the differential wiring type, it goes without saying that the ground wiring for conducting the ground wirings is not limited to the concentric layout, but may be set to a free shape for conducting the ground wirings such as a linear shape and a curved shape.

### First Embodiment

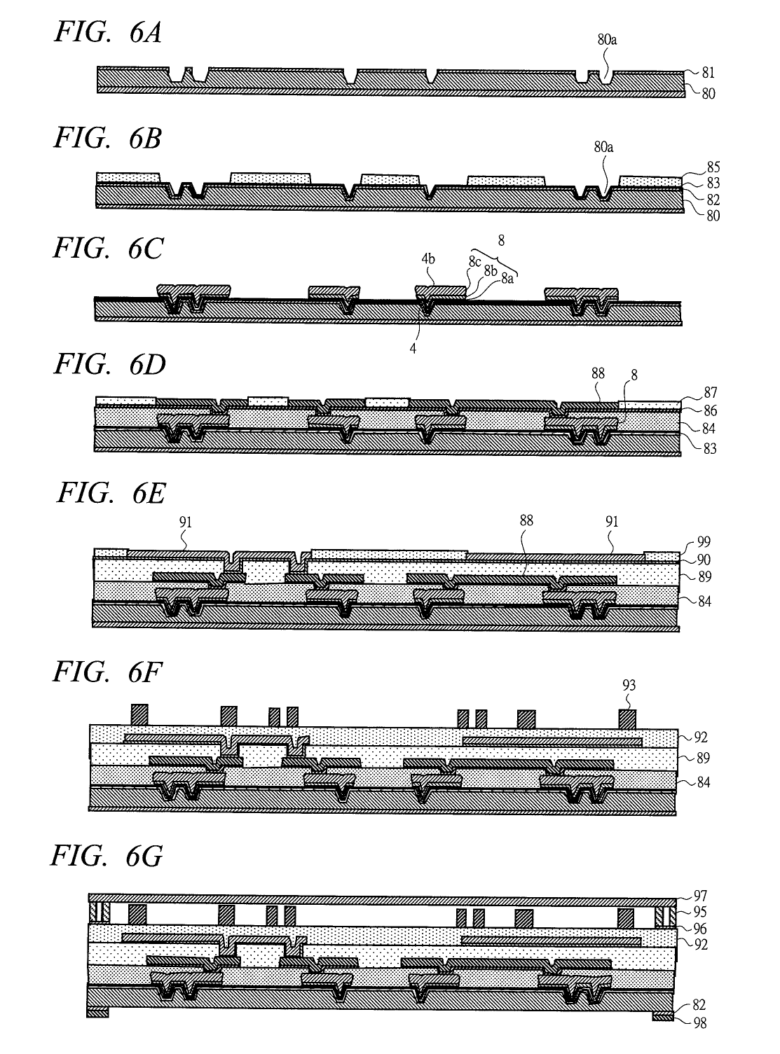

Next, a description will be given of a method of manufacturing an example of above-described probe sheet (structure) used in a probe card, with reference to FIG. 6 and FIG. 7.

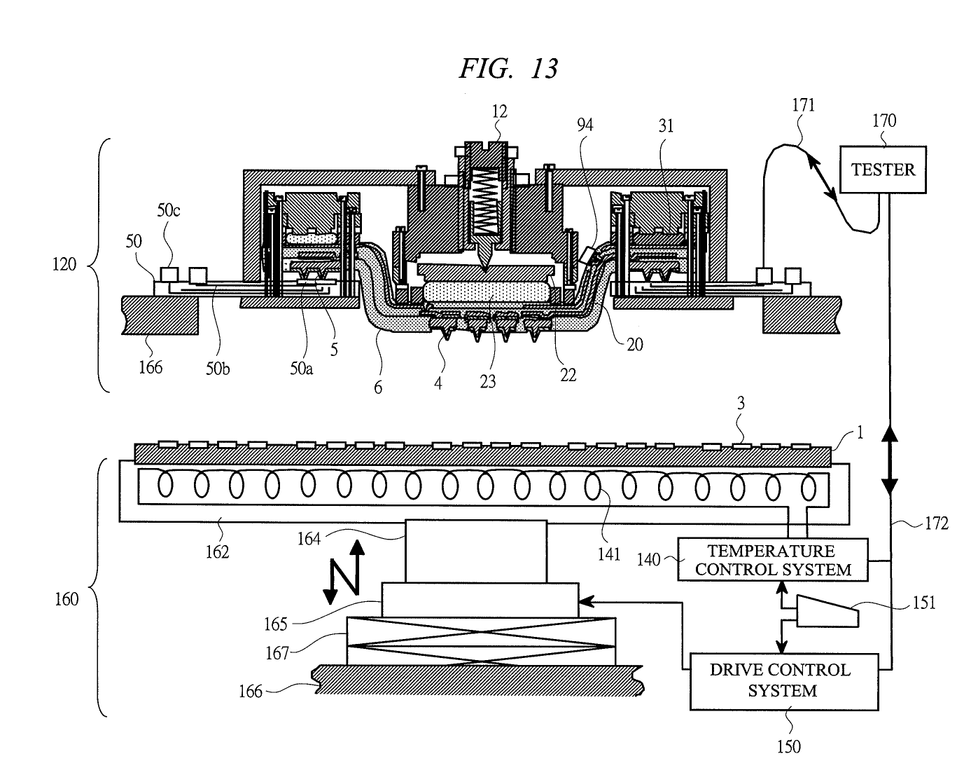

FIG. 6 particularly shows, in a manufacturing process for forming the probe shown in FIG. 13, a manufacturing process of a probe sheet 6 in the order of the process where: integrally forming a contact terminal portion 8 having a pyramidal shape contact terminal 4 formed thereon and a wiring material 88 for wiring on a polyimide film 84 by using a pyramidal shape hole (pit) as a cast formed in a silicon wafer 80 by anisotropic etching; further forming a polyimide film 89 and a wiring material 91 on a front surface thereof; further adhering a metal film 93 by an adhesive layer 92; and firmly attaching a frame 21 and a fixing plate of peripheral electrodes 9 to the metal film 93.

First, a step shown in FIG. 6A is implemented. Steps to be implemented in this process are: forming a silicon dioxide film 81 of about 0.5 μm thick formed through thermal oxidation on both surfaces of the silicon wafer 80 of (100) orientation having a thickness of 0.2 to 0.6 mm; a photoresist is applied; after a pattern is formed in which the photoresist is removed from positions to form truncated pyramid pits by photolithography, etching the silicon dioxide film 81 by a mixed solution of a hydrofluoric acid and an ammonium fluoride with the photoresist as a mask; through anisotropic etching, etching the silicon wafer 80 by a strong alkaline solution (for example, potassium hydroxide) with the silicon dioxide film 81 as a mask; and forming a truncated pyramidal shape etching pits 80a surrounded by faces of (111) orientation.

In this case, in the present embodiment, the silicon wafer 80 the cast, however, it goes without saying that the cast can be variously modified within the range if it is crystalline. Moreover, in the present embodiment, the anisotropic etching pit is formed in the truncated pyramid shape, however, the shape may be a pyramid shape, or may be variously changed within a range of a shape which can form the contact terminal 4 such a degree as to secure a stable contact resistance by a small pressure. Further, it goes without saying that the configuration may be made such that the electrode to be contacted is brought into contact with a plurality of contact terminals.

Next, a process shown in FIG. 6B is implemented. Steps to be implemented in this process are: removing the silicon dioxide film 81 used as the mask through etching by a mixed solution of the hydrofluoric acid and the ammonium fluoride; again forming a silicon dioxide film 82 about 0.5 μm thick on the whole surface of the silicon wafer 80 through thermal oxidation in wet oxygen and forming a conductive film 83 on a front surface thereof; and next, forming a photoresist mask 85 on a front surface of the conductive film 83 so as to open the contact terminal portion 8.

Next, there is implemented a step of integrally forming the contact terminal 4 and the contact electrode portion 4b by electroplating with a material having a high hardness as a main component while setting the photoresist mask 85 shown in FIG. 6C as the mask and setting the conductive film 83 as a current feeder layer, and removing the photoresist mask 85.

The contact terminal portion 8 may be formed by integrally forming the contact terminal 4 and the contact electrode portion 4b by sequentially plating the plating material having the high hardness, for example, nickel 8a, rhodium 8b, and nickel 8c.

Next, there is implemented a process shown in FIG. 6D. Steps of this process include: forming a polyimide film 84 covering the contact terminal portion 8 and the conductive film 83; removing the polyimide film 84 existing at positions at which holes for connecting wirings from the contact terminal portions 8 are expected to be formed, down to the front surface of the contact terminal portion 8; forming a conductive film 86 on the polyimide film 84; forming a photoresist mask 87; and thereafter, plating a wiring material 88.

In order to remove part of the polyimide film 84, for example, it is preferable to employ laser drilling or dry etching after forming an aluminum mask on the front surface of the polyimide film 84.

As the conductive film 86, for example, it is preferable to form a chrome film having a thickness of about 0.1 μm by depositing a film of chrome by sputtering or evaporation, and form a copper film having a thickness of about 1 μm on a front surface of the formed chrome film by sputtering or evaporation. Further, as the wiring material, it is preferable to employ a copper plated material or a material obtained by plating nickel on copper plating.

Next, there is implemented a process shown in FIG. 6E. Steps of this process include: removing the photoresist mask 87; after removing the conductive film 86 through soft etching by using the wiring material 88 as a mask, forming a polyimide film 89; removing the polyimide film 89 existing at positions at which connecting holes are expected to be formed in a wiring material 91 above the wiring material 88, down to the front surface of the wiring material 88; forming a conductive film 90 on the polyimide film 89; forming a photoresist mask 99; and thereafter plating the wiring material 91.

In order to remove part of the polyimide film 89, for example, it is preferable to employ laser drilling or dry etching after forming an aluminum mask on the front surface of the polyimide film 89.

As the conductive film 90, for example, it is preferable to form a chrome film having a thickness of about 0.1 μm by depositing a film of chrome through sputtering or the evaporation, and form a copper film having a thickness of about 1 μm by forming a film of copper on the front surface of the formed chrome film, through sputtering or evaporation. Further, as the wiring material, it is preferable to employ a copper plated material or a material obtained by plating nickel on copper plating.

Next, there is implemented a process shown in FIG. 6F. Steps of this process include: removing the photoresist mask 99; after removing the conductive film 90 through soft etching by using the wiring material 91 as a mask, adhering an adhesive layer 92 and a metal layer 93; and forming a desired metal film pattern by etching the metal film 93 with a photoresist mask.

In this case, as the adhesive layer 92, for example, it is preferable to employ a polyimide adhesive sheet or an epoxy adhesive sheet. Further, it is possible to achieve an improvement of strength and a great area of the formed probe sheet 6 by forming the metal layer 93 by laminating a metal sheet having such a low linear expansion coefficient as that of 42-alloy (an alloy constituted by 42% nickel and 58% iron and having 4 ppm/° C. linear expansion coefficient) or that of iron-nickel alloy such as inver (an alloy constituted by 36% nickel and 64% iron and having 1.5 ppm/° C. linear expansion coefficient) and close to a linear expansion coefficient of the silicon wafer (the silicon cast) 80 to the polyimide film 89 on which the wiring material 91 is formed by the adhesive layer 92. Further, it is possible to prevent displacements due to the temperature during the inspection, and it is possible to secure a positional precision under various conditions. In this major point, as the metal film 93, a material having a linear expansion coefficient close to a linear expansion coefficient of the semiconductor element to be inspected maybe employed, for the purpose of securing a positional precision during the burn-in inspection.

The adhering step mentioned above may be obtained by: overlapping the silicon wafer 80 on which the polyimide film 89, the contact terminal portion 8, and the wiring material 88 are formed, the adhesive layer 92, and the metal layer 93; and applying a temperature equal to or more than a glass transition point temperature (Tg) of the adhesive layer 92 while pressurizing under 10 to 200 kgf/cm² to adhere pressuring and heating in vacuum.

Next, there is implemented a process shown in FIG. 6G. Steps of the process include: firmly attaching a process ring 95 to the adhesive layer 92 by an adhesive agent 96; adhering a protective film 97 to the process ring 95; and etching the silicon dioxide film 82 with a mixed solution of hydrofluoric acid and ammonium fluoride by using the protective film 98 having a hollowed-out center as the mask.

In the case where a 42-alloy sheet or an iron-nickel alloy is used as the metal film 93, a spray etching by a ferric chloride solution may be implemented. Further, a photoresist mask for patterning the metal film 93 may be a liquid resist or a film resist (dry film).

Next, there is implemented a process shown in FIG. 7A. Steps of the process include: peeling the protective films 97 and 98; attaching a protection jig for silicon etching 100; and etching silicon.

For example, to etch silicon, it may be employed these steps of: screwing the process ring 95 to an intermediate fixing plate 100d; installing a stainless steel fixing jig 100a and a stainless steel lid 100b interposing an O-ring 100c therebetween; and etching the silicon wafer 80 as a cast by a strong alkaline solution (for example, potassium hydroxide).

Next, there is implemented a process shown in FIG. 7B. Steps of the process include: detaching the protection jig for silicon etching 100; adhering a protective film to the process ring 95 in such a manner as to cover one surface in the same manner as that of FIG. 6G; etching the silicon dioxide film 82, the conductive film 83 (chrome and copper), and the nickel 8a; removing the protective film; thereafter applying an adhesive agent 96b between the metal film 93 and a probe sheet frame 21, and between the metal film 93 and a fixing plate of peripheral electrodes 9; and firmly attaching the probe sheet frame 21 and the fixing plate of peripheral electrodes 9 to their predetermined positions on the metal film 93.

The silicon dioxide film 82 may be etched by a mixed solution of hydrofluoric acid and ammonium fluoride, the chrome film may be etched by potassium permanganate, and the film of copper and nickel 8a may be etched by an alkali copper etching solution.

Note that, the reason for using the plating of rhodium 8b exposed to the front surface of the contact terminal as a result of the series of etching processes is that the rhodium is hard to be attached by the solder and aluminum and the like as the material of the electrode 3, has a higher hardness than that of nickel, is hard to be oxidized, and has a stable contact resistance.

Next, there is implemented a process shown in FIG. 7C. The process includes: cutting the polyimide films 84 and 89 and the adhesive layer 92 along the probe sheet frame 21, and the outer peripheral portion of the fixing plate of peripheral electrodes 9, and manufacturing a probe sheet structure 105.

### Second Embodiment

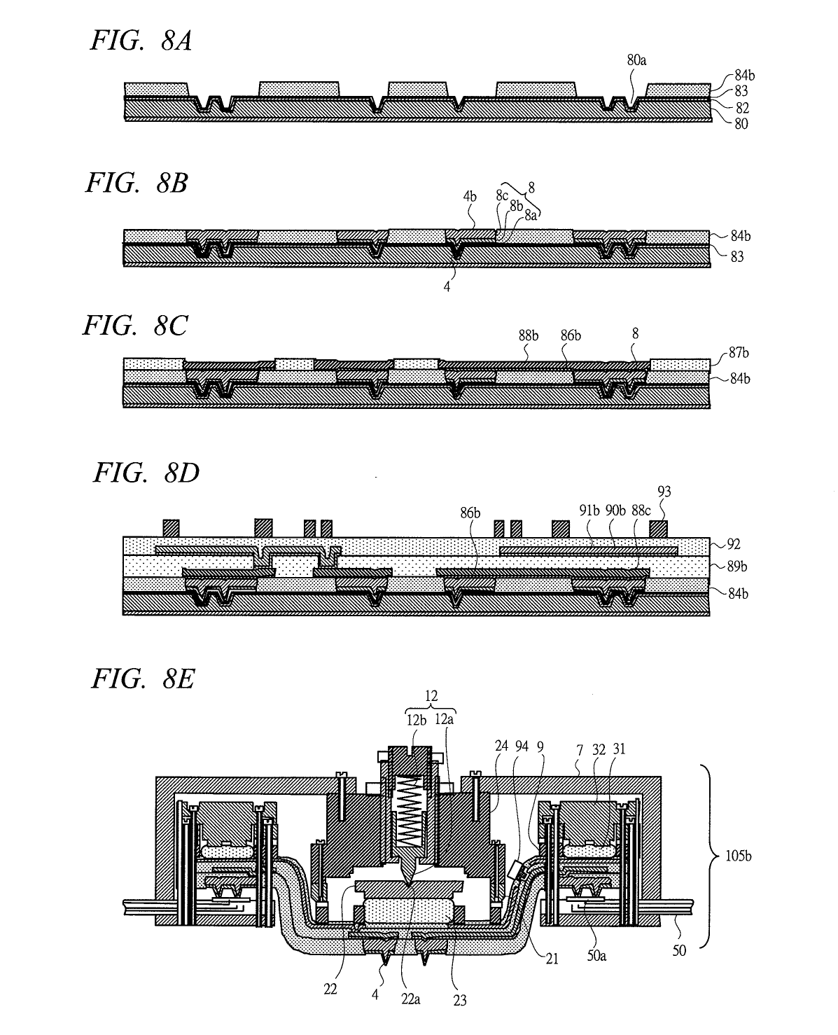

Next, a description will be given of a method of manufacturing a probe sheet according to a second embodiment, manufacturing processes of which are slightly different from the probe sheet described above, with reference to FIG. 8.

FIGS. 8A to 8E show the other manufacturing processes for forming the probe sheet in the order of the processes.

First, there is implemented these steps of: forming the pyramidal shape etching pit 80a on the silicon wafer 80 shown in FIG. 8A; forming the silicon dioxide film 82 on the front surface of the silicon wafer 80; forming the polyimide film 84b on the front surface of the conductive film 83 formed on the silicon dioxide film 82; and subsequently removing the polyimide film 84b existing at the position at which the contact terminal 4 is expected to be formed, down to the front surface of the conductive film 83.

The conductive film 83 may be obtained, for example, by forming a chrome film having a thickness of about 0.1 μm by forming a film of chrome through sputtering method or evaporation, and forming a copper film having a thickness of about 1 μm by forming a film of copper on the front surface of the formed chrome film through sputtering or evaporation. A resistance to the laser process may be increased by plating copper to be several μm thick on the copper film.

In order to remove the polyimide film 84b, for example, it may employ laser drilling or dry etching after forming an aluminum mask on the front surface of the polyimide film 84b.

Next, there is implemented a process shown in FIG. 8B. First, the contact terminal 4 and the contact electrode portion 4b are integrally formed by electrically plating a material having a high hardness as a main component on the conductive film 83 exposed at the opening of the polyimide film 84b, taking the conductive film 83 as an electrode. It is preferable to form the contact terminal portion 8 by sequentially plating materials having a high hardness, for example, nickel 8a, rhodium 8b and nickel 8c so as to integrally form the contact terminal 4 and the contact electrode portion 4b.

Next, there is implemented a process shown in FIG. 8C. Steps of the process include: forming the conductive film 86b on the contact terminal portion 8 and the polyimide film 84b; forming the photoresist mask 87b; and thereafter plating the wiring material 88b.

It is preferable that the conductive film 86b is obtained by, for example, forming a chrome film having a thickness of about 0.1 μm by forming a film of chrome through sputtering or evaporation, and forming a copper film having a thickness of about 1 μm by forming a film of copper on the front surface of the formed chrome film through sputtering or evaporation. Further, it is preferable to employ copper as the wiring material.

Next, there is implemented a step shown in FIG. 8D. Steps of the process include: removing the photoresist mask 87b; removing the conductive film 86b through soft etching by using the wiring material 88b as a mask; thereafter forming a polyimide film 89b; removing the polyimide film 89b existing at a position at which a connecting hole is expected to be formed in a wiring material 91b above the wiring material 88b, down to the front surface of the wiring material 88b; forming a conductive film 90b on the polyimide film 89b; forming a photoresist mask; and thereafter plating the wiring material 91b. Subsequently, this process comprises: removing the photoresist mask; removing the conductive film 90b through soft etching by using the wiring material 91b as a mask; thereafter adhering the adhesive layer 92 and the metal layer 93; and forming a desired metal film pattern by etching the metal film 93 with the photoresist mask.

In order to remove part of the polyimide film 89b, for example, it is preferable to employ laser drilling or dry etching after forming an aluminum mask on the front surface of the polyimide film 89b.

As the conductive film 90b, for example, it is preferable to form a chrome film having a thickness of about 0.1 μm by forming a film of chrome through sputtering or evaporation, and forming a copper film having a thickness of about 1 μm by forming a film of copper on the front surface of the formed chrome film, through sputtering or evaporation. Further, as the wiring material, it is preferable to employ a copper plated material or a material obtained by plating nickel on a copper plating.

Next, a probe sheet structure 105b shown in FIG. 8E is manufactured along the same processes as those of FIGS. 6G to 7C.

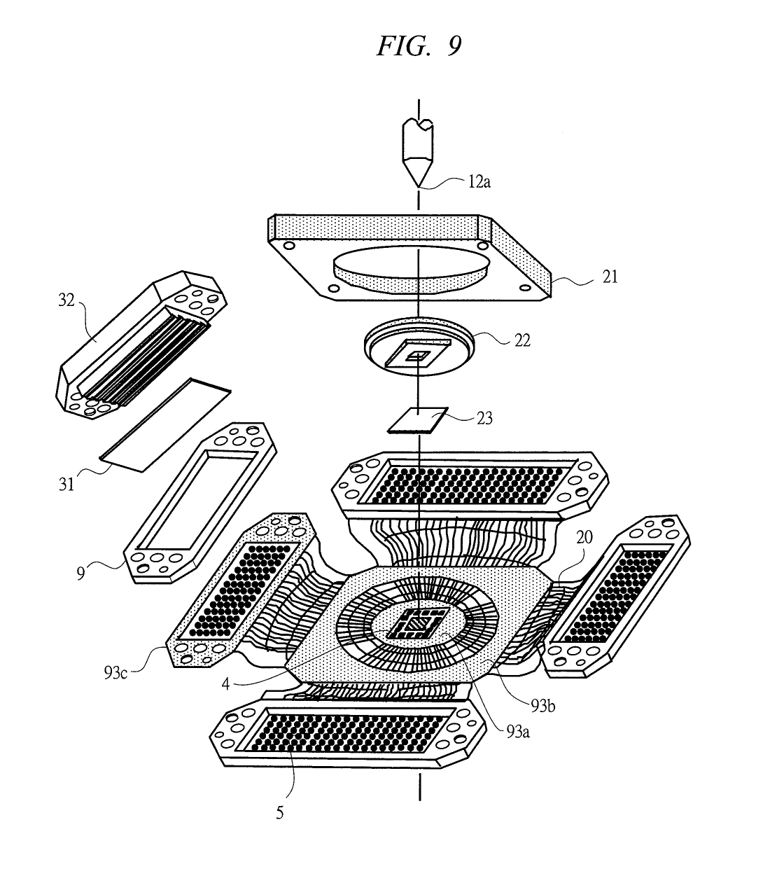

A description will be given of a cross sectional view of a main part of the probe card of the present invention shown in FIG. 7C or FIG. 8E, with reference to FIG. 9. FIG. 9 is a perspective view illustrating disintegrated main parts thereof.

The present probe card of the first or second embodiment is constituted by a support member (an upper fixing plate) 7; a spring plunger 12 fixed to a center portion of an intermediate plate 24 screwed to the support member 7 so as to be adjustable along its height direction having a tip 12a at a lower leading end so as to serve as a center pivot, and loading a spring 12b applying a pressing force to the probe sheet 6 via a pressing piece 22 movable around a leading end of the tip 12a as a supporting point; a frame 21 adhered and fixed to a back surface in such a manner as to surround a region in which a contact terminal group constituted by a plurality of contact terminals 4 of the probe sheet 6 are formed; and an intermediate plate 24 having an elastomer 23 such as a silicon sheet or the like between the region in which the contact terminal group of the probe sheet 6 is formed and the back surface of the pressing piece 22 in a center portion, and screwed to the frame 21.

In this case, the pressing piece 22 is constituted by a compliance mechanism having a structure of being held by the tip 12a at the leading end of the spring plunger 12 installed in the center portion of the intermediate plate 24 so as to be slightly tiltable, and applying (pressing) a desired approximately constant pressing force (for example, about 20 N at 150 μm pressing amount, in the case of about 500 pins) by the spring plunger 12. In this case, a conical groove 22a engaging with the tip 12a is formed at a center portion of an upper surface of the pressing piece 22.

The probe sheet 6 is configured by: forming a contact terminal group constituted by a plurality of contact terminals 4 for contacting with an electrode group constituted by a plurality of electrodes 3 of the semiconductor element 2 in a center region portion in a probing side of the sheet; forming a metal film 93a and a metal film 93b in a region corresponding to the frame 21 in such a manner as to surround a periphery of the contact terminal group doubly; forming a peripheral electrode group constituted by a plurality of peripheral electrodes 5 for giving and receiving signals with respect to a multilayer wiring substrate 50 in peripheral portions of four sides of the probe sheet 6; forming a metal film 93c in a region corresponding to the peripheral electrode fixing plate 9 in such a manner as to surround the peripheral electrode group; and forming a plurality of wirings 20a (71, 72, 74, 75, 76a and 76b) shown in FIG. 4B or FIG. 4C between the contact terminal group and the peripheral electrode group. Further, the frame 21 is adhered and fixed to the back surface of the probe sheet 6 in the region in which the contact terminal group is formed, and the peripheral electrode fixing plate 9 is adhered and fixed to the back surface of the portion in which the peripheral electrode group is formed, in the probe sheet 6 for giving and receiving the signal. Further, the frame 21 is screwed to the intermediate plate 24. The spring plunger 12 is fixed to the intermediate plate 24, and is structured such that the tip 12a at the leading end of the lower portion is engaged with the conical groove 22a formed in the center of the upper surface of the pressing piece 22.

In this case, it is possible to improve an assembling characteristic by forming, on the metal film 93c, a pattern of holes for position-determining pin and holes for inserting a screw.

The peripheral electrode group is connected to electrodes 50a of the multilayer wiring substrate 50 via an elastomer 31, by screwing a peripheral pressing plate 32 to the fixing plate of peripheral electrode 9 fixed and attached to the probe sheet 6 so as to surround the peripheral electrode group while sandwiching the elastomer 31 therebetween.

### Third Embodiment

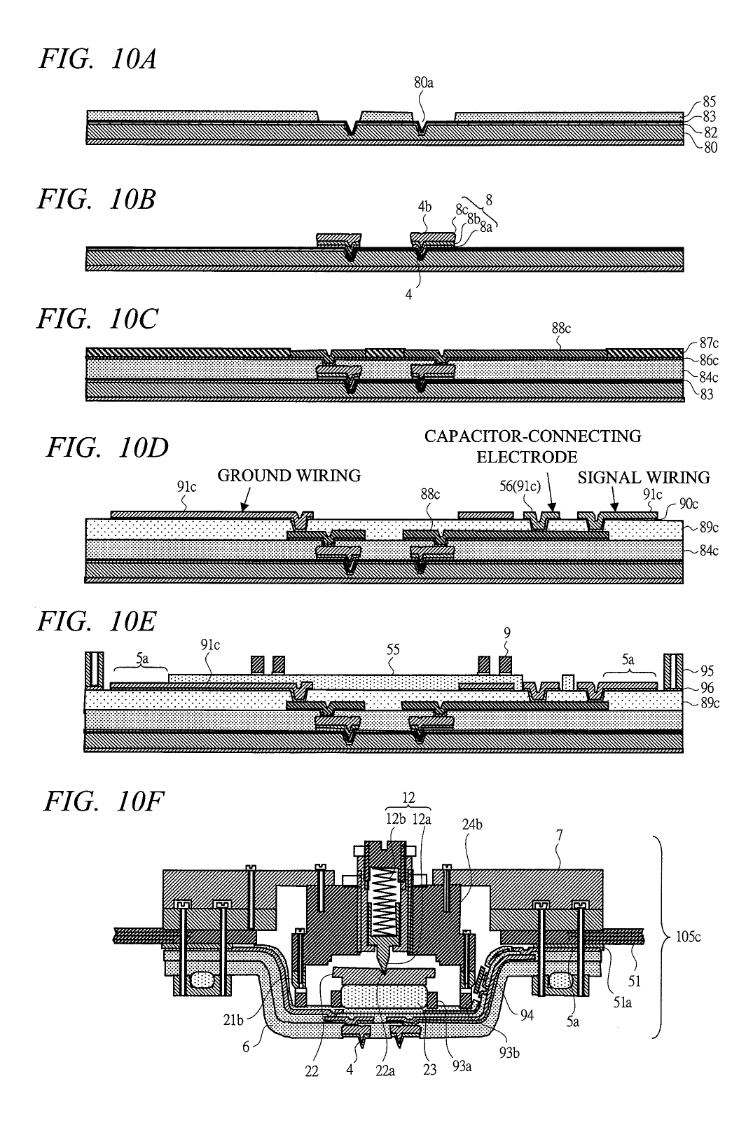

A description will be given of manufacturing processes of a method of manufacturing a probe sheet according to a third embodiment with reference to FIG. 10.

The method of manufacturing the present probe sheet is the same as the method of manufacturing the probe sheet described in FIGS. 6 and 7 except a point of a step of forming all the peripheral electrodes on an opposite surface to the surface for forming the contact terminals 4 for bringing the peripheral electrode 5a of the probe sheet into contact with the electrode 51a of the multilayer wiring substrate 51.

First, there is implemented a process shown in FIG. 10A. This process is the same processes as shown in FIGS. 6A and 6B, and implements steps of: forming a pyramidal shape etching hole on the silicon wafer 80; forming the silicon dioxide film 82 and the conductive film 83 on the front surface of the silicon wafer 80; and forming the photoresist mask 85 on the front surface of the conductive film 83 so as to open the contact terminal portion 8.

Next, there is implemented the steps of: implementing an electric plating a material having a high hardness as the main component by setting the photoresist mask 85 as a mask and setting the conductive film 83 as a current feeding layer; integrally forming the contact terminal 4 and the connecting electrode portion 4b; and removing the photoresist mask 85.

Next, there is implemented a process shown in FIG. 10C. Steps of this process include: forming a polyimide film 84c in such a manner as to cover the contact terminal portion 8 and the conductive film 83; removing the polyimide film 84c existing at the position at which the hole for connecting the wiring from the contact terminal portion 8 is expected to be formed, down to the front surface of the contact terminal portion 8; forming a conductive film 86c on the polyimide film 84c; forming a photoresist mask 87c; and thereafter plating a wiring material 88c.

Next, there is implemented a process shown in FIG. 10D. Steps of this process include: removing the photoresist mask 87c; removing the conductive film 86c through soft etching by setting the wiring material 88c as a mask; thereafter forming a polyimide film 89c; removing the polyimide film 89c existing at a position at which a hole for connecting is expected to be formed in a wiring material 91c above the wiring material 88c, down to the front surface of the wiring material 88c; forming a conductive film 90c on the polyimide film 89c; forming the photoresist mask; plating the wiring material 91c; thereafter removing the photoresist mask; and removing the conductive film 90c through soft etching by setting the wiring material 91c as a mask.

Next, there is implemented a process shown in FIG. 10E. Steps of this process include forming a polyimide film 55 in such a manner as to cover the wiring material 91c and the polyimide film 89c in an inner region of the peripheral electrode 5a, and firmly attaching the process ring 95 to the polyimide film 89c by the adhesive agent 96.

Next, a probe sheet structure 105c shown in FIG. 10F is manufactured along with the same processes as those in FIGS. 6G to 7C.

In this case, a capacitor 94 may be installed between the wiring material 91c for a capacitor-connecting electrode 56 and the wiring material 91c for the ground wiring if necessary, for stabilizing the high-speed transmission signals.

### Fourth Embodiment

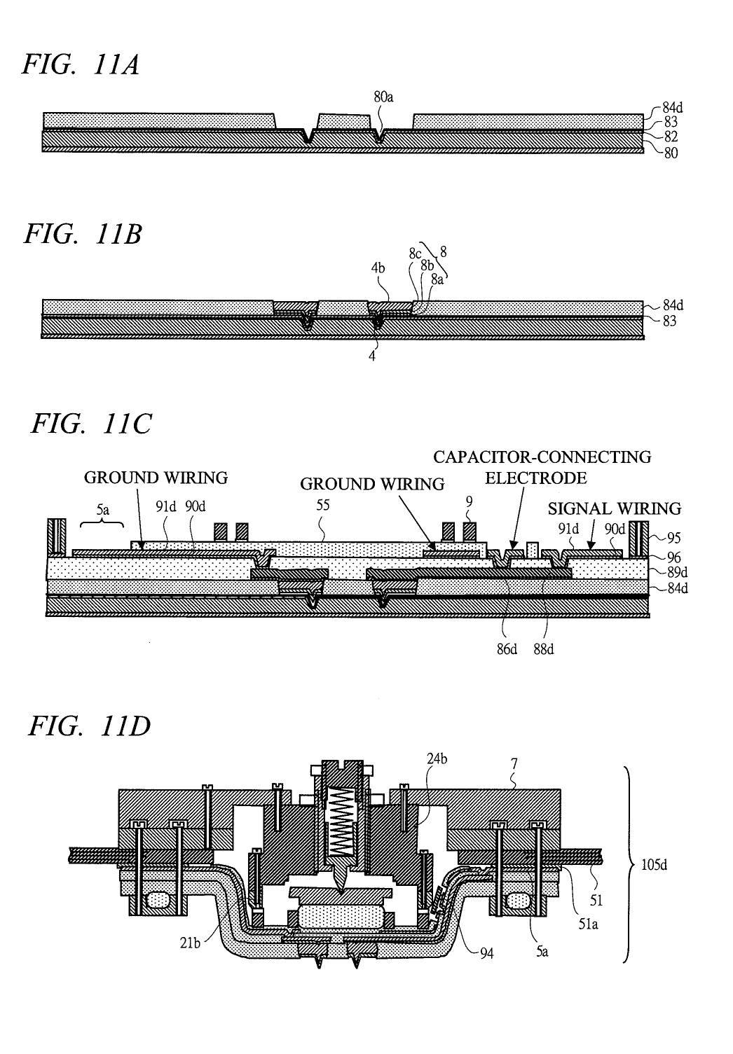

A description will be given of manufacturing processes of a method of manufacturing a probe sheet according to a fourth embodiment with reference to FIG. 11.

The method of manufacturing the present probe sheet is the same as the method of manufacturing the probe sheet described in FIG. 8 except a point of a step of forming all the peripheral electrodes on an opposite surface to the surface for forming the contact terminal 4 for bringing the peripheral electrode 5a of the probe sheet into contact with the electrode 51a of the multilayer wiring substrate 51.

First, there is implemented a process shown in FIG. 11A. Steps if this process include: forming the pyramidal shape etching hole 80a on the silicon wafer 80; forming the silicon dioxide film 82 on the front surface of the silicon wafer 80; forming the polyimide film 84d on the front surface of the conductive film 83 formed on the silicon dioxide film 82; and next removing the polyimide film 84d existing at the position at which the contact terminal 4 is expected to be formed, down to the front surface of the conductive film 83.

Next, there is implemented a process shown in FIG. 11B. Steps of this process include: first, the contact terminal 4 and the connecting electrode portion 4b are integrally formed by electrically plating a material having a high hardness as the main component onto the conductive film 83 exposed to the opening portion of a polyimide film 84d by using the conductive film 83 as an electrode. It is preferable to form the contact terminal portion 8 so as to integrally form the contact terminal 4 and the contact electrode portion 4b by sequentially plating the plating material having a high hardness, for example, nickel 8a, rhodium 8b, and nickel 8c.

Next, there is implemented a process shown in FIG. 1C. Steps of this process include: plating a wiring material 88d after forming a conductive film 86d on the contact terminal portion 8 and the polyimide film 84d; and forming a photoresist mask. Next steps are: removing the photoresist mask; removing the conductive film 86d through soft etching by setting the wiring material 88d as a mask; thereafter forming a polyimide film 89d; removing the polyimide film 89d existing at a position at which a hole for connecting is expected to be formed in a wiring material 91d above the wiring material 88d, down to the front surface of the wiring material 88d; forming a conductive film 90d on the polyimide film 89d; forming a photoresist mask; and thereafter plating the wiring material 91d. Subsequent steps are: removing the photoresist mask; removing the conductive film 90d though soft etching by setting the wiring material 91d as a mask; thereafter forming the polyimide film 55 in such a manner as to cover the wiring material 91d and the polyimide film 89d in an inner region of the peripheral electrode 5a; and firmly attaching the process ring 95 to the polyimide film 89d by the adhesive agent 96.

Next, a probe sheet structure 105d shown in FIG. 11D is manufactured along with the same processes as those in FIGS. 6G to 7C.

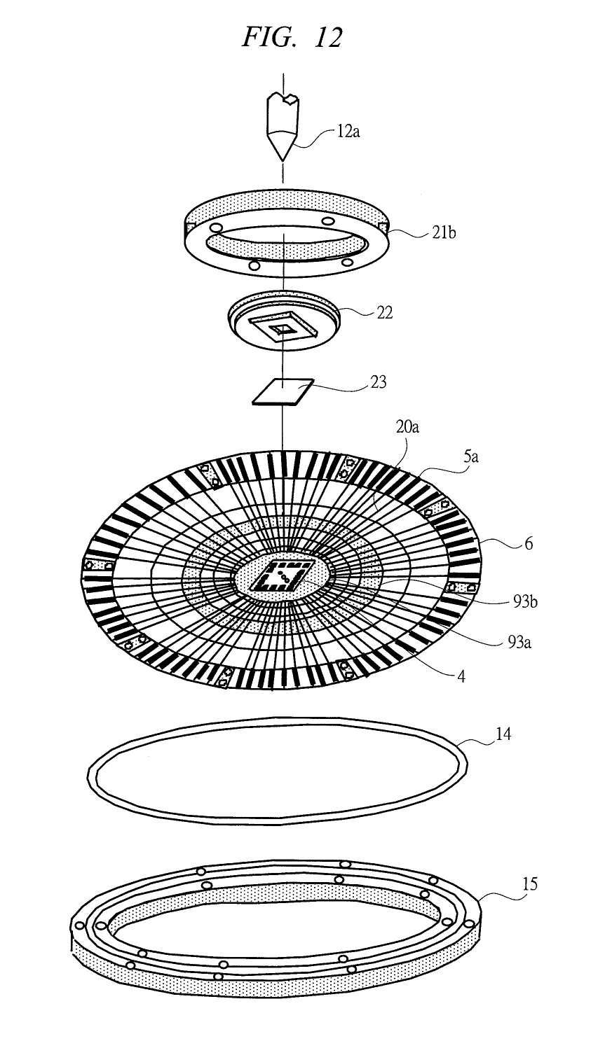

A description will be given of a cross sectional view showing a main part of a probe card according to the present invention shown in FIG. 10F or 11D, with reference to FIG. 12. FIG. 12 is a perspective view illustrating dismounted main parts thereof.

The present probe card of the third or fourth embodiment is comprised by: the support member (upper fixing plate) 7; the spring plunger 12 fixed to a center portion of an intermediate plate 24b screwed to the support member 7 so as to be adjustable along its height direction, having the tip 12a at a lower leading end so as to serve as a center pivot, and loading the spring 12b applying a pressing force to the probe sheet 6 via the pressing piece 22 movable around a leading end of the tip 12a as a supporting point; a frame 21b adhered and fixed to a back surface in such a manner as to surround a region in which the contact terminal group constituted by the plurality of contact terminals 4 of the probe sheet 6 are formed; and the intermediate plate 24b having the elastomer 23 such as a silicon sheet or the like between the region in which the contact terminal group of the probe sheet 6 is formed and the back surface, and the pressing piece 22 in a center portion, and screwed to the frame 21b.

In this case, the pressing piece 22 is constituted by a compliance mechanism having a structure of being held by the tip 12a at the leading end of the spring plunger 12 installed in the center portion of the intermediate plate 24b so as to be slightly tiltable, and applying (pressing) a desired approximately constant pressing force (for example, about 20 N at 150 μm pressing amount, in the case of about 500 pins) by the spring plunger 12. In this case, the conical groove 22a engaging with the tips 12a is formed at a center portion of an upper surface of the pressing piece 22.

The probe sheet 6 is configured by: forming a contact terminal group constituted by the plurality of contact terminals 4 for contacting with the electrode group constituted by the plurality of electrodes 3 of the semiconductor element 2 in a center region portion in a probing side of the sheet; forming the metal film 93a and the metal film 93b in a region corresponding to the frame 21b in such a manner as to surround a periphery of the contact terminal group doubly; forming the peripheral electrode group constituted by a plurality of peripheral electrodes 5a for giving and receiving signals with respect to a multilayer wiring substrate 51 in peripheral portions of four sides of the probe sheet 6; and forming the plurality of wirings 20a (71, 72, 74, 75, 76a and 76b) shown in FIG. 4B or FIG. 4C between the contact terminal group and the peripheral electrode group. Further, the frame 21b is adhered and fixed to the back surface of the probe sheet 6 in an outer periphery of the region in which the contact terminal group is formed, and the frame 21b is screwed to the intermediate plate 24b. The spring plunger 12 is fixed to the intermediate plate 24b, and is structured such that the tip 12a at the leading end of the lower portion is engaged with the conical groove 22a formed in the center of the upper surface of the pressing piece 22.

The peripheral electrode group is connected to the electrode 51a of the multilayer wiring substrate 51 via an O-ring 14 installed in such a manner as to face to the back surface of the peripheral electrode group of the probe sheet 6, by screwing an O-ring presser foot 15 to the multilayer wiring substrate 51 while sandwiching the O-ring 14.

Next, a description will be given of a semiconductor inspection system using the probe card (probing device) according to the present invention described above, with reference to FIG. 13.

FIG. 13 is a diagram showing a whole structure of an inspection system including the semiconductor inspection system according to the present invention. FIG. 13 shows an inspection system implementing an electric characteristic inspection by applying a desired load to the surface of the wafer 1. In this state, the load of the spring plunger 12 is applied to the whole contact terminals, and an electric signal for inspection is given and received with respect to a tester 170 implementing an inspection of the electric characteristic of the semiconductor element through the contact terminal 4 brought into contact with the electrode 3 of the wafer 1, a wiring 20, the peripheral electrode 5, the electrode 50a of the multilayer wiring substrate 50, the internal wiring 50b, and the electrode 50c.

In the whole structure of the inspection system, the probe card is constructed as a wafer prober. The inspection system comprises: a sample support system 160 supporting the wafer 1 as an inspected subject; a probe card 120 brought into contact with the electrode 3 of the wafer 1 so as to give and receive electric signals; a driving control system 150 controlling an operation of the sample support system 160; a temperature control system 140 implementing a temperature control of the wafer 1; and a tester 170 implementing an inspection of electric characteristics of the semiconductor element (chip) 2. The wafer 1 is structured such that a plurality of semiconductor elements (chips) are arranged, and a plurality of electrodes 3 serving as the external connecting electrode are arranged on a front surface of each of the semiconductor elements.

The sample support system 160 is constituted by: a wafer stage 162 detachably mounting the wafer 1 and provided approximately horizontally; an elevating shaft 164 vertically arranged in such a manner as to support the wafer stage 162; an elevation driving portion 165 driving so as to ascend and descend the elevating shaft 164; and an X-Y stage 167 supporting the elevation driving portion 165. The X-Y stage 167 is fixed onto a chassis 166. The elevation driving portion 165 is constituted by, for example, a stepping motor or the like. A positioning operation in a horizontal direction and a vertical direction of the wafer stage 162 is implemented by a combination of a moving operation of the X-Y stage 167 within a horizontal surface, and an ascending and descending operation by the elevation driving portion 165, or the like. Further, the wafer stage 162 is provided with a rotating mechanism (not shown), and a rotating displacement of the wafer stage 162 can be achieved within the horizontal surface.

The probe system constituted by the probe card 120 is arranged above the wafer stage 162. In other words, for example, the probe card 120 using the probe sheet structure shown in FIG. 7C and the multilayer wiring substrate 50 are provided in a posture facing to the wafer stage 162 in parallel. Each of the contact terminals 4 is connected to the electrode 50c provided on the multilayer wiring substrate 50 through the electrode 50a and the internal wiring 50b of the multilayer wiring substrate 50 via the wiring 20 and the peripheral electrode 5 provided on the probe sheet 6 of the probe card 120, and is connected to the tester 170 via a cable 171 connected to the electrode 50c.

The driving control system 150 is connected to the tester 170 via the cable 172. Further, the driving control system 150 sends a control signal to an actuator in each of driving portions of the sample support system 160 to control an operation thereof. In other words, the driving control system 150 is provided with a computer in an internal portion, and controls the operation of the sample support system 160 in correspondence to progress information of a test operation of the tester 170 transmitted via the cable 172. Further, the driving control system 150 is provided with an operation portion 151, and accepts an input of various commands relating to the driving control, for example, a command of a manual operation.

The wafer stage 162 is provided with a heater 141 for heating the semiconductor element 2. The temperature control system 140 controls the temperature of the wafer 1 mounted on the wafer stage 162 by controlling the heater 141 of the wafer stage 162 or a cooling jig. Further, the temperature control system 140 is provided with the operating portion 151, and accepts an input of various commands relating to a temperature control, for example, a command of a manual operation. In this case, it is possible to control the temperature by working a temperature controllable heat generating body provided in a part of the probe sheet or the probe card in conjunction with the heater 141 of the wafer stage 162.

A description will be given below of an operation of the semiconductor inspection system. First, the wafer 1 as the inspected subject is positioned so as to be mounted on the wafer stage 162, an X-Y stage 167 and a rotating mechanism are controlled driving, the electrode group constituted by a plurality of electrodes 3 formed on a plurality of semiconductor elements arranged on the wafer 1 is positioned just below the contact terminal group constituted by a plurality of contact terminals 4 provided side by side to the probe card 120. Thereafter, the driving control system 150 actuates the elevation driving portion 165 and ascends the wafer stage 162 until the whole surface of a plurality of electrodes (contacted materials) 3 comes to a state of being lifted up about 30 to 100 μm above from a point where the contact with the leading end of the contact terminal obtained, thereby protruding the region in which a plurality of contact terminals 4 are provided side by side in the probe sheet 6 so as to parallel push each leading end of the contact terminal group constituted by a plurality of contact terminals 4 in which a flatness is secured at a high precision in such a manner as to follow the surface of (the whole of) the electrode group surface constituted by a plurality of electrodes 3 arranged on the semiconductor element by a compliance mechanism (a pressing mechanism). Accordingly, it is possible to achieve the contact by the pressing on the basis of the uniform load (about 3 to 150 mN per one pin) so as to follow each of the contacted materials (the electrodes) 3 arranged on the wafer 1, and it is possible to connect each of the contact terminals 4 and each of the electrodes 3 with a low resistance (0.01Ω to 0.1Ω).

Further, the operation characteristic of the semiconductor element or the like is discriminated by giving and receiving an operating current, an operation inspection signal and the like between the semiconductor element formed on the wafer 1 and the tester 170, via the cable 171, the multilayer wiring substrate 50, and the contact terminal 4. Further, the series of inspection operations mentioned above are implemented on each of a plurality of semiconductor elements formed on the wafer 1, and the operating characteristic or the like is discriminated.

In the present embodiment described above, there is shown the probe sheet structure having the structure in FIG. 7C, however, the present invention is not limited to this, but can be variously modified within the scope of the present invention. It goes without saying that it is possible to employ, for example, a probe sheet structure as shown in FIG. 8E, 10F or 11D.

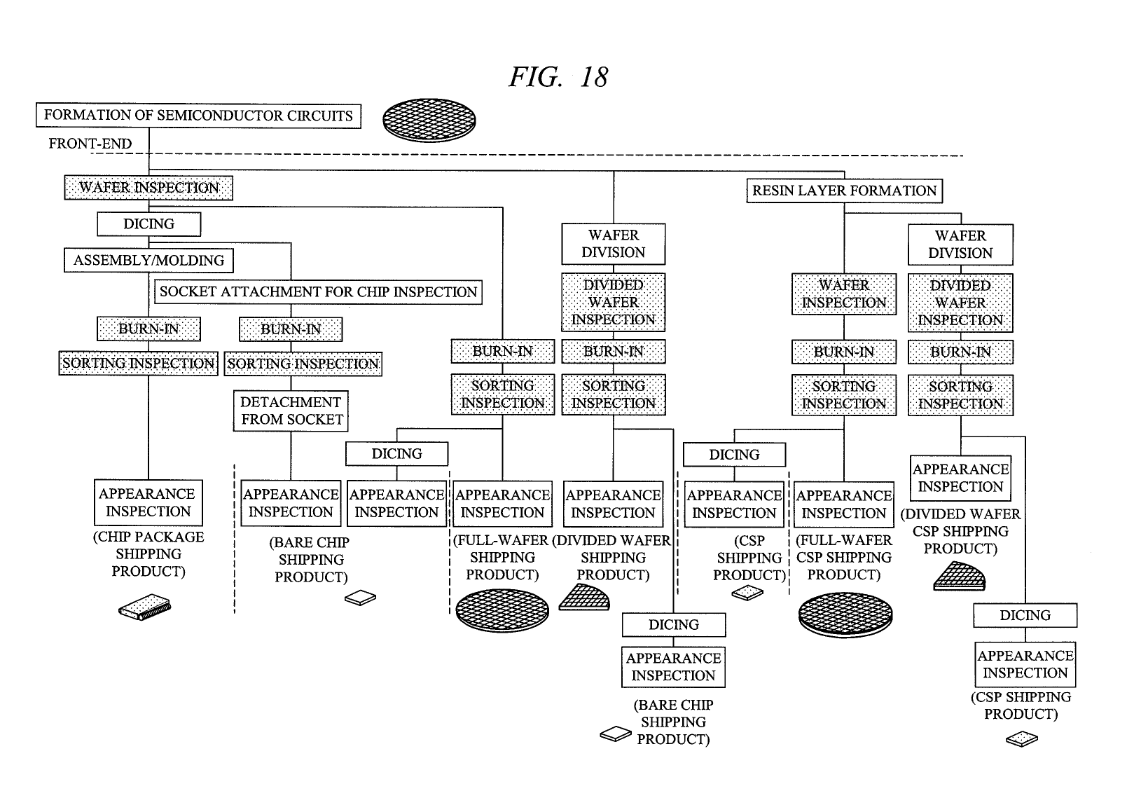

In this case, a description will be given of a representative example, of a method of manufacturing a semiconductor device including an inspecting step or an inspecting method using the above semiconductor inspection system, with reference to FIG. 18.

(1) A method of manufacturing a semiconductor device according to the present invention has: a step of forming circuits on a wafer and forming semiconductor devices (i.e., a semiconductor element circuit formation); a step of inspecting electric characteristics of a plurality of semiconductor devices in a lump by wafer level by the semiconductor inspection system according to the present invention (i.e., a wafer inspection); a step of cutting the wafer so as to divide per the semiconductor element (i.e., dicing); and a step of molding the semiconductor element by a resin or the like (i.e., assembly and molding). Thereafter, the semiconductor device is shipped as a chip package product via the burn-in inspection, the sorting inspection and the appearance inspection.

(2) A method of manufacturing a semiconductor device according to the present invention has: a step of forming circuits on the wafer to form semiconductor devices (i.e., semiconductor element circuit formation); a step of inspecting the electric characteristics of a plurality of semiconductor elements in a lump by wafer level by the semiconductor inspection system according to the present invention (i.e., wafer inspection); and a step of cutting the wafer so as to divide per the semiconductor element (i.e., dicing). Thereafter, the semiconductor device is shipped as a bare chip product through installation of a socket for the chip inspection, burn-in inspection, sorting inspection, detachment from the socket, and the appearance inspection.

(3) A method of manufacturing a semiconductor device according to the present invention has a step of forming a circuit in the wafer and forming the semiconductor device (i.e., a semiconductor element circuit formation) and a step of inspecting the electric characteristics of a plurality of semiconductor devices in a lump at wafer level by the semiconductor inspection system according to the present invention (i.e., wafer inspection). Thereafter, the semiconductor device is shipped as a full wafer product via the burn-in inspection, the sorting inspection and the appearance inspection. In the burn-in inspection and the sorting inspection, the inspections are implemented by the semiconductor inspection system according to the present invention.

(4) A method of manufacturing a semiconductor device according to the present invention has a step of forming a circuit in the wafer and forming the semiconductor device (i.e., semiconductor element circuit formation) and a step of inspecting the electric characteristics of a plurality of semiconductor devices in a lump at wafer level by the semiconductor inspection system according to the present invention (i.e., wafer inspection). Thereafter, the semiconductor device is shipped as a bare chip product via the burn-in inspection and the appearance inspection, and via a step of cutting the wafer so as to divide per the semiconductor element (i.e., dicing), and the appearance inspection. In the burn-in inspection and the sorting inspection, the inspections are implemented also by the semiconductor inspection system according to the present invention.

(5) A method of manufacturing a semiconductor device according to the present invention has: a step of forming circuits on the wafer and forming the semiconductor device (a semiconductor element circuit formation); a step of dividing the wafer (i.e., wafer division); and a step of inspecting the electric characteristics of a plurality of semiconductor devices in a lump at divided wafer level by the semiconductor inspection system according to the present invention (i.e., divisional wafer inspection). Thereafter, the semiconductor device is shipped as a divided wafer product via the burn-in inspection, the sorting inspection and the appearance inspection. In the burn-in inspection and the sorting inspection, the inspections are implemented also by the semiconductor inspection system according to the present invention.

(6) A method of manufacturing a semiconductor device according to the present invention has: a step of forming a circuit in the wafer and forming the semiconductor device (i.e., semiconductor element circuit formation); a step of dividing the wafer (i.e., wafer division); and a step of inspecting the electric characteristics of a plurality of semiconductor devices in a lump in a divided wafer level by the semiconductor inspection system according to the present invention (i.e., divisional wafer inspection). Thereafter, the semiconductor device is shipped as a bare chip product via: the burn-in inspection; the sorting inspection; a step of cutting the divided wafer so as to divide per the semiconductor element (i.e., dicing); and the appearance inspection. In the burn-in inspection and the sorting inspection, the inspections are implemented also by the semiconductor inspection system according to the present invention.

(7) A method of manufacturing a semiconductor device according to the present invention has: a step of forming circuits on the wafer to form the semiconductor device (i.e., semiconductor element circuit formation); a step of forming a resin layer or the like on the wafer (i.e., resin layer formation); and a step of inspecting the electric characteristics of a plurality of semiconductor elements formed on the wafer, on which the resin layer or the like is formed, in a lump by the semiconductor inspection system according to the present invention (i.e., wafer inspection). Thereafter, the semiconductor device is shipped as a CSP product via: the burn-in inspection; the sorting inspection; a step of cutting the wafer so as to divide per the semiconductor element (i.e., dicing); and the appearance inspection. In the burn-in inspection and the sorting inspection, the inspections are implemented also by the semiconductor inspection system according to the present invention.

(8) A method of manufacturing a semiconductor device according to the present invention has: a step of forming circuits on the wafer and forming the semiconductor device (i.e., semiconductor element circuit formation); a step of forming a resin layer or the like on the wafer (i.e., resin layer formation); and a step of inspecting the electric characteristics of a plurality of semiconductor elements formed on the wafer, on which the resin layer or the like is formed, in a lump by the semiconductor inspection system according to the present invention (i.e., wafer inspection). Thereafter, the semiconductor device is shipped as a full wafer CSP product via the burn-in inspection, the sorting inspection, and the appearance inspection. In the burn-in inspection and the sorting inspection, the inspections are implemented also by the semiconductor inspection system according to the present invention.

(9) A method of manufacturing a semiconductor device according to the present invention has: a step of forming circuits on the wafer to form the semiconductor device (i.e., semiconductor element circuit formation); a step of forming a resin layer and the like on the wafer (i.e., resin layer formation); a step of dividing the wafer on which the resin layer and the like are formed (i.e., wafer division); and a step of inspecting the electric characteristics of a plurality of semiconductor devices in a lump at divided wafer level by the semiconductor inspection system according to the present invention (i.e., divided wafer inspection). Thereafter, the semiconductor device is shipped as a divided wafer CSP product via the burn-in inspection, the sorting inspection, and the appearance inspection. In the burn-in inspection and the sorting inspection, the inspections are implemented also by the semiconductor inspection system according to the present invention.

(10) A method of manufacturing a semiconductor device according to the present invention has: a step of forming circuits on the wafer to form the semiconductor device (i.e., semiconductor element circuit formation); a step of forming a resin layer or the like on the wafer (i.e., resin layer formation); a step of dividing the wafer on which the resin layer and the like are formed (i.e., wafer division); and a step of inspecting the electric characteristics of a plurality of semiconductor devices in a lump in a divided wafer level by the semiconductor inspection system according to the present invention (i.e., divided wafer inspection). Thereafter, the semiconductor device is shipped as a CSP product via: the burn-in inspection; the sorting inspection; a step of cutting the wafer so as to divide per the semiconductor element (i.e., dicing); and the appearance inspection. In the burn-in inspection and the sorting inspection, the inspection is implemented also by the semiconductor inspection system according to the present invention.

In the steps of inspecting the electric characteristics of the semiconductor element in the methods of manufacturing the semiconductor device described above, it is possible to achieve inspections with improved high-speed transmission characteristic, by using the probe card in which the transmission circuit according to the present invention is formed.

In other words, the high-speed transmitting wiring sheet on which the ground of radial mesh pattern according to the present invention is formed can mitigate an increase of rigidity of the sheet posed by the metal for forming the ground, thereby applying flexibility to the sheet.

Further, since it is possible to design the signal wiring width wide even if the thickness of the insulating sheet is small, by removing the ground layer on the facing surface just below the insulating sheet forming the signal wiring so as to form the ground wiring structure of radial mesh pattern, it is possible to reduce a loss of the high-speed transmission signal in which the transmission on the front surface region is mainly achieved due to the skin effect.

Further, even if the transmission circuit pattern according to the present invention is employed, the displacement of the signal wiring and the ground wiring less affect. Accordingly, there is created a margin in a mask aligning positional precision in manufacturing the high-speed transmission sheet. As a result, there is created a margin in forming the transmission circuit, therefore, it is possible to manufacture the sheet in which the high-speed transmission characteristic is secured.

### Fifth Embodiment

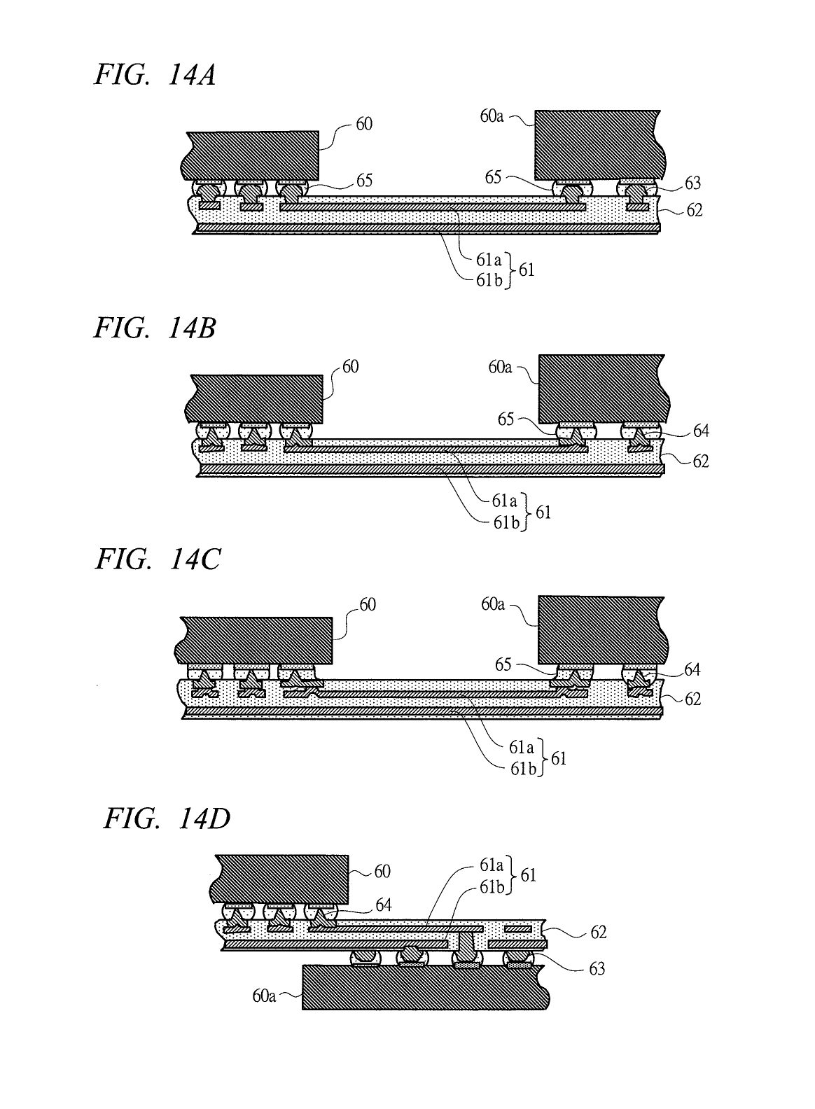

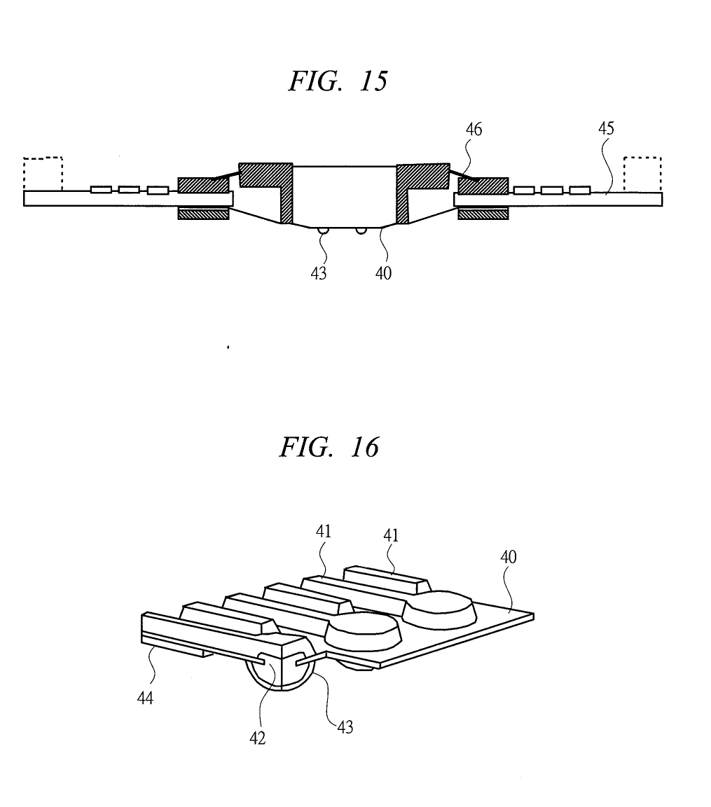

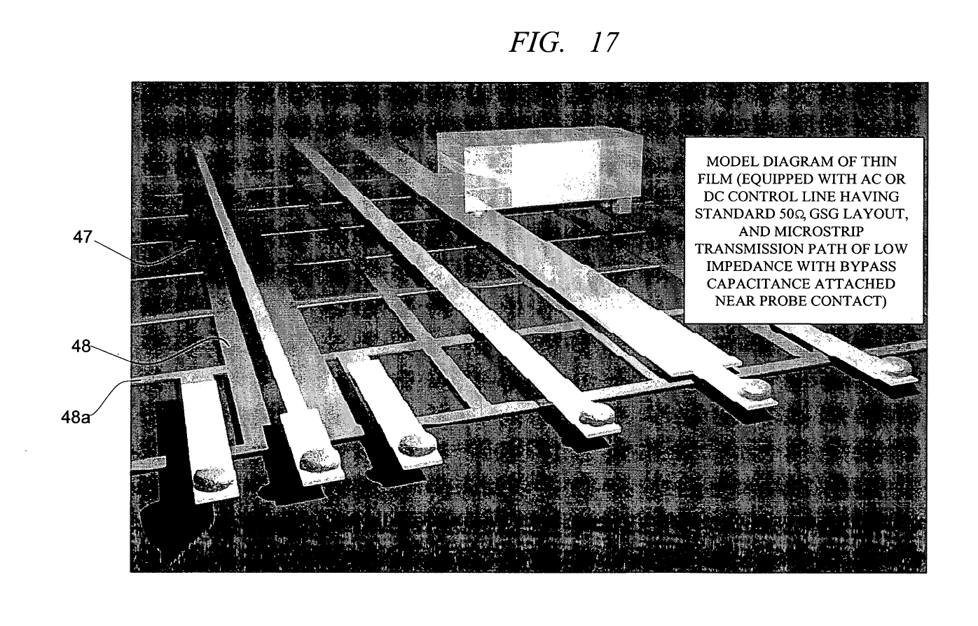

Next, a description will be given of a structure of an application example of the high-speed transmitting circuit according to the present invention shown in FIG. 2A-1 or FIG. 3A-1, with reference to FIG. 14.

FIGS. 14A to 14D show embodiments in which the transmission circuit 61 shown in FIG. 2A-1 or FIG. 3A-1 is formed in the wiring sheet 62 for giving and receiving the signal between a plurality of semiconductor devices 60 and 60a. It is preferable to stabilize the ground level by forming a ground wiring 78b for conduction between the ground transmission wirings shown in FIGS. 4B and 4C as a mesh-shaped ground pattern, as needed. In the connection between the semiconductor devices 60 and 60a, for example, it is preferable to connect a plating bump 63 shown in FIG. 14A, or a contact terminal 64 of square truncated pyramidal shape shown in FIGS. 14B and 14C to the solder bump 65. Further, as shown in FIG. 14D, it is possible to use both of the plating bump 63 and the contact terminal 64 of square truncated pyramidal shape.

In the present embodiment, there is shown the example in which the plating bump 63 or the s contact terminal 64 of square truncated pyramidal shape is connected to the solder bump 65, as the contact terminal, however, it goes without saying that it is possible to employ every connection method, for example, the connection only by the solder bump, and a supersonic connection between the metals, as far as it can form the high-speed transmitting circuit according to the present invention shown in FIG. 2A-1 or FIG. 3A-1.

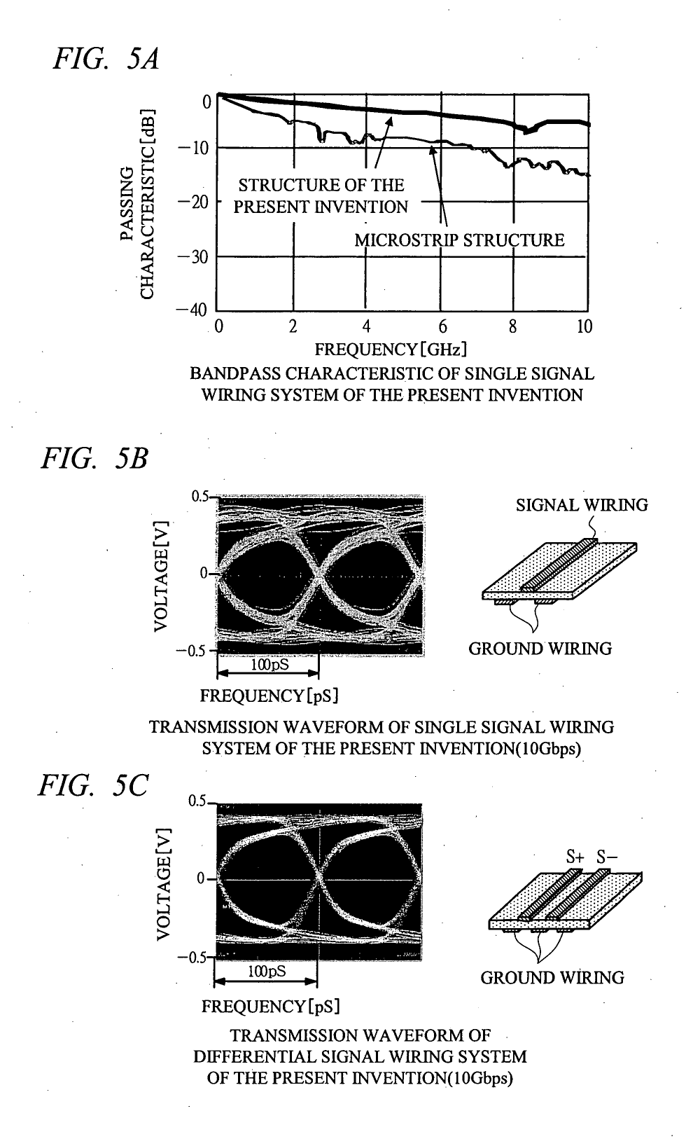

Finally, results of measurement of the probe card of the system of FIG. 12 manufactured on the basis of the present invention will be shown in FIGS. 5A, 5B, and 5C.

FIG. 5A is a view showing a bandpass characteristic of a single signal wiring method according to the present invention and a bandpass characteristic of a microstrip structure having the same size of the probe sheet. Both the drawings show a case that the impedance is aligned with 50±2Ω, and it shows that the transmission system according to the present invention is better.

FIG. 5B shows a transmission waveform of 10 Gbps of the single signal wiring system according to the present invention, and FIG. 5C shows a transmission waveform of 10 Gbps of a differential signal wiring system according to the present invention. The transmission waveforms (eye patterns) of the both indicate its excellence in a high-speed transmission characteristic (5 to 10 Gbps).

As described above, according to the results of measurement of the probe card manufactured on the basis of the present invention, it is found that it is possible to achieve a circuit for the high-speed transmission having a good transmission characteristic and an excellent high-speed transmission characteristic.

In the foregoing, the invention made by the inventors of the present invention has been concretely described based on the embodiments. However, it is needless to say that the present invention is not limited to the foregoing embodiments and various modifications and alterations can be made within the scope of the present invention.

The effects obtained by typical aspects of the present invention will be briefly described below.

The wiring sheet for the high-speed transmission on which the ground wiring of radial mesh pattern according to the present invention is formed has the following effects in comparison with the sheet in which the microstrip line is formed by forming the ground layer on the whole surface of the back surface.

(1) It is possible to mitigate an increase of rigidity of a sheet of the metal for forming the ground by employing a ground wiring structure of radial mesh pattern so that it is possible to apply flexibility to the sheet.

(2) In the case of the same thickness of the insulating sheet and aligned with the same impedance, it is possible to design the signal wiring width wide in comparison with the signal wiring width of the microstrip line, by removing the ground layer on the facing surface just below the insulating sheet forming the signal wiring so as to form the ground wiring of radial mesh pattern structure. As a result, it is possible to reduce the loss of the high-speed transmission signal in which the transmission in the surface region becomes main due to the skin effect.

The invention may be embodied in other specific forms without departing from the spirit or essential characteristics thereof. The present embodiment is therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A transmission circuit having a signal wiring formed on an upper surface of an insulating layer, and a ground wiring formed on a lower surface of the insulating layer,
wherein the transmission circuit is designed by a wiring structure where the ground wiring just below the signal wiring while sandwiching the insulating layer is partly removed.

2. A transmission circuit having a signal wiring formed on an upper surface of an insulating layer, and a ground wiring formed on a lower surface of the insulating layer,
wherein the transmission circuit is designed by a wiring structure where the ground wiring just below the signal wiring while sandwiching the insulating layer is partly removed, and the signal wiring and the ground wiring are formed in a radial pattern.

3. The transmission circuit according to claim 2,
wherein one or a plurality of wirings conducting the ground wirings mutually are provided in the middle of the ground wirings of the radial pattern.

4. The transmission circuit according to claim 1,
wherein the ground wiring is formed by two ground wirings which are spaced at a width equal to or more than a width of the signal wiring, and have a width smaller than the twofold width of the signal wiring.

5. The transmission circuit according to claim 1,
wherein the signal wiring is formed by a differential line pair, one ground wiring is provided just below a position between the lines of the differential line pair, and the ground wirings are provided on surfaces below outer sides of the differential line pair respectively.

6. The transmission circuit according to claim 5,
wherein an interval of the differential line pair is equal to or more than the width of the differential wiring, and the ground wiring is formed by a ground wiring having a width smaller than the twofold width of the differential wiring.

7. A probe sheet comprising: contact terminals for wafer electrodes disposed corresponding to an arrangement of electrodes of semiconductor elements formed on a wafer; wirings drawn from the contact terminals for connecting wafer electrodes; and contact terminals for a substrate electrically connected to the wiring,
wherein the wirings configure the transmission circuit according to claim 1.

8. The probe sheet according to claim 7,
wherein the contact terminals for wafer electrodes are formed by using anisotropic etching pits of a single crystal substrate as the cast of the contact terminals.

9. The probe sheet according to claim 7,
wherein both of the contact terminals for wafer electrodes and the contact terminals for the substrate are formed by using anisotropic etching pits of the single crystal substrate as the cast of contact terminals.

10. A probe card comprising: contact terminals for wafer electrodes brought into contact with electrodes provided on a wafer; wirings drawn from the contact terminals for wafer electrodes; contact terminals for a substrate electrically connected to the wirings; and a multilayer wiring substrate having electrodes electrically connected to the contact terminals for the substrate,
wherein the wirings configure the transmission circuit according to claim 1.

11. The probe card according to claim 10,
wherein the contact terminals for wafer electrodes are configured by pyramidal shape or truncated pyramidal shape terminals formed by using anisotropic etching pits of a single crystal substrate as the cast of contact terminals.

12. A semiconductor inspection system comprising: a wafer stage to mount a wafer thereon; contact terminals for wafer electrodes brought into contact with electrodes of semiconductor elements formed on the wafer; and a probe card electrically connected to a tester to test electric characteristics of the semiconductor elements,
wherein the probe card has contact terminals for wafer electrodes brought into contact with electrodes provided on the wafer, wirings drawn from the contact terminals for wafer electrodes, contact terminals for a substrate electrically connected to the wirings, and a multilayer wiring substrate provided with electrodes electrically connected to the contact terminals for the substrate,
wherein the wirings configure the transmission circuit according to claim 1.

13. The semiconductor inspection system according to claim 12,
wherein both or one of the contact terminals for wafer electrodes and the contact terminals for the substrate are in pyramidal shape or truncated pyramidal shape formed by using anisotropic etching pits of a single crystal substrate as the cast of contact terminals.

14. A method of manufacturing a semiconductor device including the steps of: forming circuits on a wafer so as to form semiconductor elements; inspecting electric characteristics of the semiconductor elements; and dicing the wafer so as to divide per the semiconductor element,
wherein the step of inspecting electric characteristics of the semiconductor elements inspects the semiconductor elements by using: a probe sheet comprising contact terminals for wafer electrodes brought into contact with electrodes of the semiconductor elements, wirings drawn from the contact terminals for wafer electrodes, and contact terminals for a substrate electrically connected to the wirings; and a probe card comprising a multilayer wiring substrate having electrodes electrically connected to the contact terminals for the substrate, and the wirings configure the transmission circuit according to claim 1.

15. A method of manufacturing a semiconductor device including the steps of: forming circuits on a wafer so as to form semiconductor elements; molding the wafer by a resin; and inspecting electric characteristics of the semiconductor elements formed on the molded wafer,
wherein the step of inspecting electric characteristics of the semiconductor elements inspects the semiconductor element by using: a probe sheet comprising contact terminals for wafer electrodes brought into contact with electrodes of the semiconductor elements, wirings drawn from the contact terminals for wafer electrodes, and contact terminals for a substrate electrically connected to the wirings; and a probe card comprising a multilayer wiring substrate having electrodes electrically connected to the contact terminals for the substrate, and the wirings configure the transmission circuit according to claim 1.

16. The method of manufacturing a semiconductor device according claim 14,
wherein both or one of the contact terminals for wafer electrodes and the contact terminals for the substrate are in pyramidal shape or truncated pyramidal shape formed by using anisotropic etching pits of a single crystal substrate as the cast of contact terminals.

17. A connecting sheet comprising: a first contact terminal for an electrode to be contacted with an electrode provided on a first contact subject; a second contact terminal for an electrode to be contacted with an electrode provided on a second contact subject; and wirings drawn to the second contact terminal for an electrode from the first contact terminal for an electrode,
wherein the wirings configure the transmission circuit according to claim 1.

18. The connecting sheet according to claim 17,
wherein both or one of the first contact terminal for an electrode and the second contact terminal for an electrode are formed by using anisotropic etching pits of a single crystal substrate as the cast of contact terminals.
